(19) United States
(12) Patent Application Publication
(10) Pub. No.: US 2025/0287516 A1
(43) Pub. Date: Sep. 11, 2025

(54) ELECTRONIC DEVICE COMPRISING ELASTIC STRUCTURE SUPPORTING CONNECTING MEMBER

(71) Applicant: Samsung Electronics Co., Ltd., Suwon-si (KR)

(72) Inventors: Sungjung KIM, Suwon-si (KR); Sukchul PARK, Suwon-si (KR); Shinhyung LEE, Suwon-si (KR); Dongeon LIM, Suwon-si (KR); Jinho PARK, Suwon-si (KR); Jiman PAENG, Suwon-si (KR)

(21) Appl. No.: 19/219,600

(22) Filed: May 27, 2025

Related U.S. Application Data
(63) Continuation of application No. PCT/KR2023/019347, filed on Nov. 28, 2023.

(30) Foreign Application Priority Data
Nov. 29, 2022 (KR) 10-2022-0163168
Jan. 11, 2023 (KR) 10-2023-0004004

(51) Int. Cl. H05K 5/00

(52) U.S. Cl. CPC H05K 5/006; H05K 5/0069

(57) ABSTRACT

An electronic device according to an example embodiment may include a housing including a plate part, a first circuit board disposed in the plate part adjacent to one side of the housing, which faces a first direction, a second circuit board disposed in the plate part adjacent to an opposite side of the housing, which faces a second direction being opposite to the first direction, a rear case coupled to the plate part to cover at least a portion of the second circuit board, an elastic structure coupled to the plate part adjacent to the second circuit board, and configured to provide an elastic force, and a connecting member connecting the first circuit board and the second circuit board, and a portion of which contacts the elastic structure. The rear case may include a first protruding part facing a portion of the elastic structure and a portion of the connecting member, which contacts the elastic structure. In addition, various embodiment recognized through the specification are possible.

### CROSS-REFERENCE TO RELATED APPLICATIONS

This application is a continuation application of International Application No. PCT/KR2023/019347, filed on Nov. 28, 2023, in the Korean Intellectual Property Receiving Office, and claiming priority to Korean Patent Application No. 10-2022-0163168 filed Nov. 29, 2022, and Korean Patent Application No. 10-2023-0004004, filed on Jan. 11, 2023, the disclosures of which are all hereby incorporated by reference herein in their entireties.

### TECHNICAL FIELD

Certain example embodiments may relate to an electronic device including an elastic structure that supports a flexible printed circuit board (FPCB).

### Background Art

In an electronic device, one or more printed circuit boards (PCBs) may be disposed in an interior of a housing. For example, the printed circuit boards may be disposed at an upper end and a lower end of the electronic device, respectively. The board disposed at the upper end and the board disposed at the lower end may be electrically connected to each other through a connecting member, such as a flexible printed circuit board (FPCB). The connecting member may be moved in the interior of the electronic device when the electronic device is moved or an impact is applied to the electronic device.

### SUMMARY

An electronic device according to an example embodiment may include a housing including a plate part, a first circuit board disposed in the plate part adjacent to one side of the housing, which faces a first direction, a second circuit board disposed in the plate part adjacent to an opposite side of the housing, which faces a second direction being opposite to the first direction, a rear case coupled, directly or indirectly, to the plate part to cover at least a portion of the second circuit board, an elastic structure, comprising elastic material, coupled, directly or indirectly, to the plate part adjacent to the second circuit board, and configured to provide an elastic force, and a connecting member (e.g., a flexible circuit comprising conductive material and dielectric material) direct or indirectly electrically connecting the first circuit board and the second circuit board, and a portion of which contacts the elastic structure. The rear case may include a first protruding part, comprising a protrusion, facing a portion of the elastic structure and a portion of the connecting member, which contacts the elastic structure.

An electronic device according to an example embodiment may include a housing including a side member, wherein the side member may include a plate part and a frame part surrounding a periphery of the plate part, a first circuit board disposed in the plate part adjacent to one side of the housing, which faces a first direction, a second circuit board disposed in the plate part adjacent to an opposite side of the housing, which faces a second direction being opposite to the first direction, a rear case coupled, directly or indirectly, to the plate part to cover at least a portion of the second circuit board, an elastic structure coupled, directly or indirectly, to the plate part adjacent to the second circuit board, and configured to provide an elastic force, and a connecting member connecting the first circuit board and the second circuit board, and a portion of which contacts the elastic structure. Movement of the connecting member may be guided in an interior of the housing based on elastic deformation of the elastic structure.

### BRIEF DESCRIPTION OF DRAWINGS

FIG. 1 is a block diagram of an electronic device in a network environment, according to an example embodiment.

FIG. 2A is a front perspective view of an electronic device according to an example embodiment.

FIG. 2B is a rear perspective view of an electronic device according to an example embodiment.

FIG. 3 is an exploded perspective view of an electronic device according to an example embodiment.

FIG. 4A is a rear perspective view of an electronic device according to an example embodiment.

FIG. 4B is a rear perspective view of an electronic device according to an example embodiment.

FIG. 5 is a view illustrating an elastic structure of an electronic device according to an example embodiment.

FIG. 6 is a view illustrating a connecting member and an elastic structure of an electronic device according to an example embodiment.

FIG. 7 is a view illustrating driving of an elastic structure of an electronic device according to an example embodiment.

FIG. 8 is a view illustrating a rear case and a connecting member of an electronic device according to an example embodiment.

FIG. 9A is a cross-sectional view of an electronic device according to an example embodiment.

FIG. 9B is a cross-sectional view of an electronic device according to an example embodiment.

FIG. 10 is a view illustrating a rear case and a connecting member of an electronic device according to an example embodiment.

FIG. 11 is a cross-sectional view of an electronic device according to an example embodiment.

FIG. 12 is a view illustrating driving of an elastic structure and movement of a connecting member of an electronic device according to an example embodiment.

FIG. 13 is a view illustrating an operation of assembling an elastic structure, a second circuit board, a connecting member, and a second rear case of an electronic device according to an example embodiment.

FIG. 14 is a view illustrating a connecting member and an elastic structure of an electronic device according to an example embodiment.

FIG. 15 is a view illustrating an elastic structure of an electronic device according to an example embodiment.

FIG. 16 is a view illustrating a connecting member and an elastic structure of an electronic device according to an example embodiment.

FIG. 17 is a view illustrating an elastic structure of an electronic device according to an example embodiment.

FIG. 18 is a view illustrating a connecting member and an elastic structure of an electronic device according to an example embodiment.

FIG. 19 is a view illustrating an elastic structure of an electronic device according to an example embodiment.

With regard to description of the drawings, the same or similar components will be denoted by the same or similar reference numerals.

### DETAILED DESCRIPTION

Hereinafter, various embodiments of the disclosure will be described with reference to accompanying drawings. However, those of ordinary skill in the art will recognize that modification, equivalent, and/or alternative on various embodiments described herein can be variously made without departing from the scope and spirit of the disclosure.

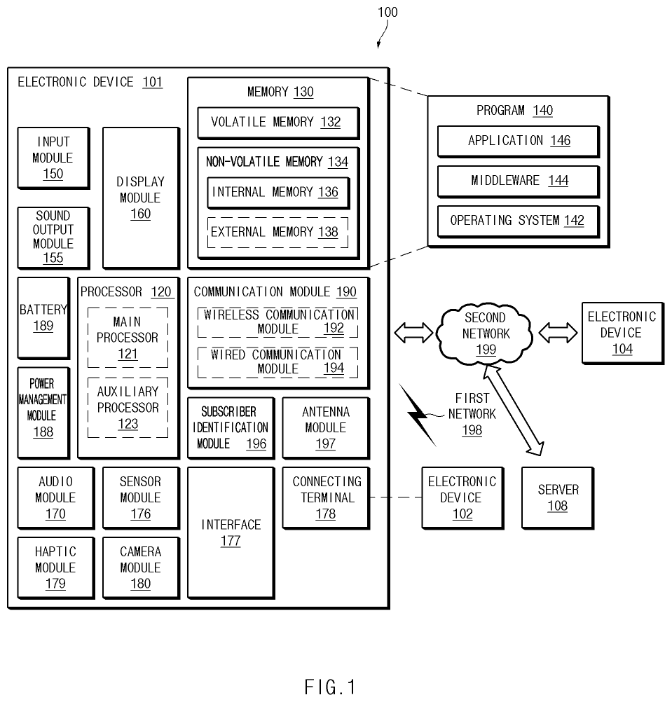

FIG. 1 is a block diagram illustrating an electronic device 101 in a network environment 100 according to certain embodiments.

Referring to FIG. 1, the electronic device 101 in the network environment 100 may communicate with an electronic device 102 via a first network 198 (e.g., a short-range wireless communication network), or an electronic device 104 or a server 108 via a second network 199 (e.g., a long-range wireless communication network). According to an embodiment, the electronic device 101 may communicate with the electronic device 104 via the server 108.

According to an embodiment, the electronic device 101 may include a processor 120 comprising processing circuitry, a memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In certain example embodiments, at least one (e.g., the connecting terminal 178) of the components may be omitted from the electronic device 101, or one or more other components may be added in the electronic device 101. In certain example embodiments, some of the components may be implemented as single integrated circuitry. For example, some (e.g., the sensor module 176, the camera module 180, or the antenna module 197) of the components may be implemented as embedded in the display module 160 (e.g., a display).

The processor 120 may execute, for example, software (e.g., a program 140) to control at least one other component (e.g., a hardware or software component) of the electronic device 101 coupled, directly or indirectly, with the processor 120, and may perform various data processing or computation. According to an embodiment, as at least part of the data processing or computation, the processor 120 may load a command or data received from another component (e.g., the sensor module 176 or the communication module 190) in a volatile memory 132, process the command or the data stored in the volatile memory 132, and store resulting data in a non-volatile memory 134. According to an embodiment, the processor 120 may include a main processor 121 (e.g., a central processing unit (CPU) or an application processor (AP)), and an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. When the electronic device 101 includes the main processor 121 and the auxiliary processor, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., a neural network processing device) may include a hardware structure specified for processing an artificial intelligence (AI) model. The AI model may be generated through machine learning. The learning may be performed by the electronic device 101 performing the AI, and may be performed through an additional server (e.g., the server 108). A learning algorithm may include, for example, a supervised learning algorithm, an unsupervised learning algorithm, a semi-supervised learning algorithm, or a reinforcement learning algorithm, but the disclosure is not limited thereto. The AI model may include a plurality of artificial neural network (ANN) layers. The ANN may include a deep neural network (DNN), a convolutional neural network (CNN), a recurrent neural network (RNN), a restricted boltzman machine (RBM), a deep belief network (DBN), a bidirectional recurrent deep neural network (BRDNN), a deep Q-networks or the combination of the above networks, but the disclosure is not limited thereto. The AI model may additionally or alternatively include a software structure, in addition to a hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by other component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record, and the receiver may be used for an incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or an external electronic device (e.g., the electronic device 102) (e.g., speaker of headphone) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). The corresponding communication module from among the communication modules may communicate with the external electronic device via the first network 198 (e.g., a short-range communication network, such as Bluetooth™, wireless-fidelity (WiFi) direct, or infrared data association (IrDA)) or the second network 199 (e.g., a long-range communication network, such as a legacy cellular network, 5G network, next generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify or authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network and a next-generation communication technology, for example, a new radio (NR) access technology after a 4G network. The NR access technology may support high-speed transmission for high capacity data (enhanced mobile broadband; eMBB), terminal power minimizing and multiple terminal access (massive machine type communication; mMTC), or ultra-reliable and low-latency communications (URLLC). The wireless communication module 192 may support a high-frequency band (e.g., mmWave band) to achieve, for example, a higher data rate. The wireless communication module 192 may support various technologies, for example, beamforming, massive multiple-input and multiple-output (MIMO), Full-dimensional MIMO, an array antenna, analog beam-forming, or a large-scale antenna, to secure performance in high frequency bands. The wireless communication module 192 may support various requirements defined in the electronic device 101, the external electronic device (e.g., the electronic device 104) or the network system (e.g., the second network 199). According to an embodiment, the wireless communication module 192 may support a peak data rate (e.g., 20 Gbps or more) for eMBB realization, loss coverage (e.g., 164 dB or less) for mMTC realization, or U-plane latency (e.g., 0.5 ms or less, or the round trip of 1 ms or less in each of a downlink (DL) and an uplink (UL)) for URLCC realization.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., PCB). According to an embodiment, the antenna module 197 may include a plurality of antennas (e.g., an array antenna). In such a case, at least one antenna appropriate for a communication scheme used in the communication network, such as the first network 198 or the second network 199, may be selected, for example, by the communication module 190 from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to certain embodiments, the antenna module 197 may form an mmWave antenna module. According to an embodiment, the mmWave antenna module may include a printed circuit board, an RFIC disposed on a first surface (e.g., a bottom surface) of the printed circuit board, or disposed adjacent to the first surface to support the specific high frequency band (e.g., mmWave band), and a plurality of antennas (e.g., an array antenna) disposed on a second surface (e.g., a top surface or a side surface) of the printed circuit board or disposed adjacent to the second surface to transmit or receive a signal having the specified high frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the external electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, when the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide an ultra-latency service by using, for example, distributed computing or mobile edge computing. According to certain embodiments, the external electronic device 104 may include the Internet of things (IoT). The server 108 may be an artificial server using machine learning and/or a neural network. According to an embodiment, the external electronic device 104 or the server 108 may be included in the second network 199. The electronic device 101 may be applied to an artificial intelligence service (e.g., a smart home, a smart city, a smart car, or healthcare service) based on the 5G communication technology and the IoT-related technology.

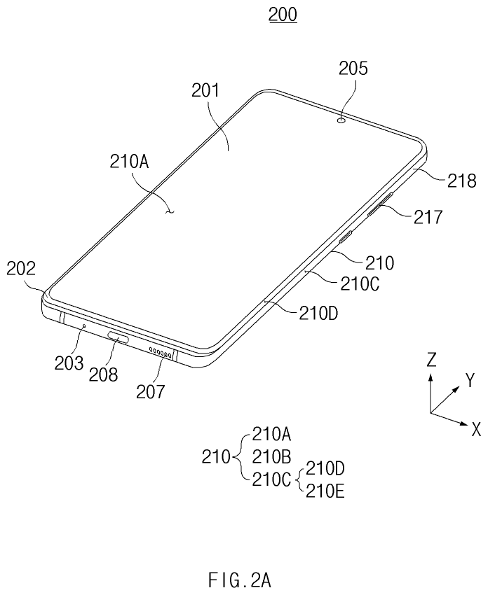

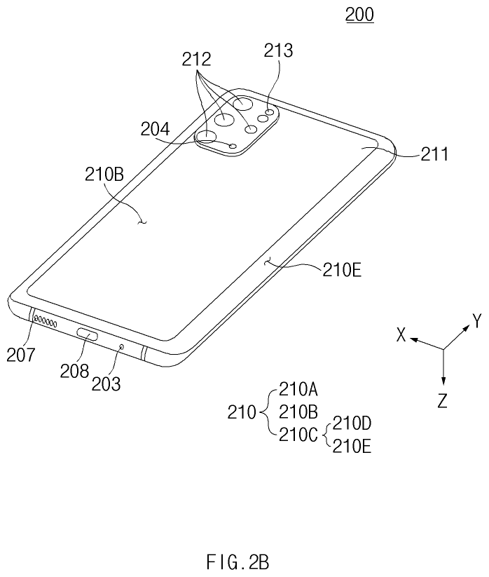

FIG. 2A is a front perspective view of an electronic device according to an embodiment. FIG. 2B is a rear perspective view of an electronic device according to an embodiment.

Referring to FIGS. 2A and 2B, an electronic device 200 (e.g., the electronic device 101 of FIG. 1) according to an embodiment may include a housing 210 including a first surface (or a front surface) 210A, a second surface (or a rear surface) 210B, and a third surface (or a side surface) 210C that surrounds a space between the first surface 210A and the second surface 210B. In various embodiments, the housing 210 may refer to a structure that defines a portion of the first surface 210A, the second surface 210B, and the third surface 210C.

The first surface 210A may be of or include a front plate 202 (e.g., a glass plate including various coating layers, or a polymer plate), at least a portion of which is substantially transparent. The second surface 210B may be of or include a rear plate 211 that is substantially opaque. The rear plate 211, for example, may be formed by coated or colored glass, ceramic, a polymer, a metal (e.g., aluminum, stainless steel (STS), or magnesium), or a combination of at least two of the materials. The third surface 210C may be coupled, directly or indirectly, to the front plate 202 or the rear plate 211 and may be of or include a side bezel structure (or a side member) 218 including a metal and/or a polymer. In various embodiments, the rear plate 211 and the side bezel structure 218 may be integrally formed, and may include the same material (e.g., a metallic material, such as aluminum).

The front plate 202 may include two first areas 210D that are bent from a partial area of the first surface 210A toward the rear plate 211 and extend seamlessly. The first areas 210D may be located at opposite ends of a long edge of the front plate 202.

The rear plate 211 may include two second areas 210E that are bent from a partial area of the second surface 210B toward the front plate 202 and extend seamlessly. The second areas 210E may be included at opposite ends of a long edge of the rear plate 211.

In various embodiments, the front plate 202 (or the rear plate 211) may include only one of the first areas 210D (or the second areas 210E). Furthermore, in various embodiments, the front plate 202 (or rear plate 211) may not include some of the first areas 210D (or the second areas 210E).

The electronic device 200 may include at least one of a display 201 (e.g., the display module 160 of FIG. 1), an audio module 203, 204, and 207 (e.g., the audio module 170 of FIG. 1), a sensor module (not illustrated) (e.g., the sensor module 176 of FIG. 1), a camera module 205, 212, and 213 (e.g., the camera module 180 of FIG. 1), a key input device 217 (e.g., the input device 150 of FIG. 1), a light emitting element (not illustrated), and a connector hole 208 (e.g., the connection terminal 178 of FIG. 1). In an embodiment, the electronic device 200 may not include at least one (e.g., the key input device 217 or the light emitting element (not illustrated)) of the components or may further include any other component.

The display 120 may be visually exposed through a corresponding portion of the front plate 121. For example, at least a portion of the display 201 may be visually exposed through the front plate 202 including the first surface 210A, and the first area 210D of the third surface 210C. The display 201 may be disposed on a rear surface of the front plate 202.

The corners of the display 201 may be formed to have substantially the same shape as an adjacent outer shape of the front plate 102. In various embodiments, to increase an area, in which the display 201 is exposed, an interval between an outer side of the display 201 and an outer side of the front plate 202 may be formed to be substantially the same.

A surface (or the front plate 202) of the housing 110 may include a screen display area that is formed as the display 201 is visually exposed. For example, the screen display area may include the first surface 210A, and the first areas 210D on the side surface.

In various embodiments, the screen display areas 210A and 210D may include sensing areas (not illustrated) that is configured to acquire the user's biometric information. Here, the meaning of “the screen display areas 210A and 210D including sensing areas” may be understood as at least a portion of the sensing areas overlapping the screen display areas 210A and 210D. For example, the sensing area (not illustrated) may mean an area, in which visual information may be displayed by the display 201 as in the other areas of the screen display areas 210A and 210D, and the user's biometric information (e.g., fingerprint) may be additionally acquired.

The screen display areas 210A and 210D of the display 201 may include an area, in which the first camera module 205 (e.g., a punch hole camera) is visually exposed. For example, at least a portion of a periphery of an area, in which the first camera module 205 is visually exposed may be surrounded by the screen display areas 210A and 210D.

In various embodiments, the display 201 may be configured such that at least one of an audio module (not illustrated), a sensor module (not illustrated), a camera module (e.g., the first camera module 205), and a light emitting element (not illustrated) is disposed on rear surfaces of the screen display areas 210A and 210D. For example, the electronic device 200 may be configured such that the first camera module 205 (e.g., an under display camera (UDC)) is disposed on a rear surface (e.g., a surface that faces the −z-axis direction) of the first surface 210A (e.g., the front surface) to face the first surface 210A. For example, the first camera module 205 may be disposed under the display 201, and may not be visually exposed to the screen display areas 210A and 210D.

In various embodiments, when the first camera module 205 is configured as an under display camera, an area of the display 201, which faces the first camera module 205, is a portion of a display area that displays contents, and may be formed as a transmissive area having a specified transmittance. For example, the transmissive area may be formed to have a transmittance in a range of about 5% to about 50%. The transmissive area may include an area that overlaps an effective area (e.g., a field of view (FOV) area) of the first camera module 205, through which light for generating an image passes by forming an image by an image sensor. For example, the transmissive area of the display 201 may include an area having a lower pixel density and/or a lower wiring line density than those of the surrounding area.

The display 201 may be coupled, directly or indirectly, to a touch sensing circuit, a pressure sensor that may measure an intensity (or pressure) of a touch, and/or a digitizer that detects a magnetic stylus pen or may be disposed to be coupled or adjacent thereto.

The audio module 203, 204, and 207 may include microphone holes 203 and 204 and a speaker hole 207.

The microphone holes 203 and 204 may include a first microphone hole 203 that is formed in a partial area of the third surface 210C and a second microphone hole 204 that is formed in a partial area of the second surface 210B. A microphone (not illustrated) for acquiring external sound may be disposed in the microphone holes 203 and 204. The microphone may include a plurality of microphones to sense a direction of sound.

The second microphone hole 204 formed in a partial area of the second surface 210B may be disposed adjacent to the camera modules 205, 212, and 213. For example, the second microphone hole 204 may acquire sound when the camera modules 205, 212, and 213 are executed, or may acquire sound when other functions are executed.

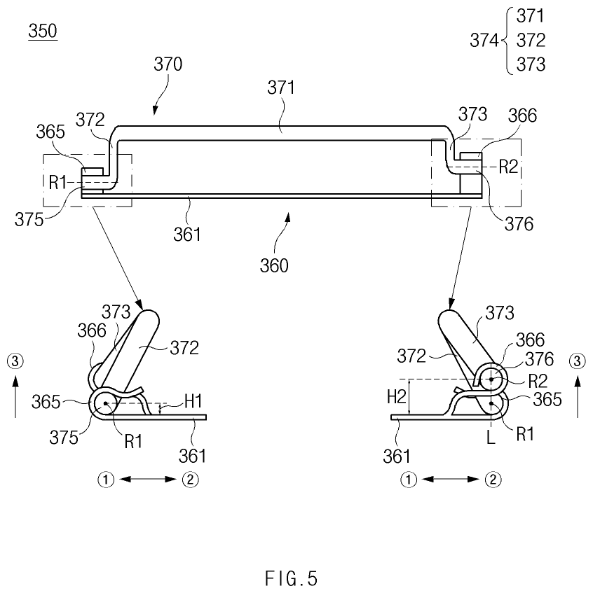

The speaker hole 207 may include an external speaker hole 207 and a receiver hole (not illustrated) for a call. The external speaker hole 207 may be formed at a portion of the third surface 210C of the electronic device 200. In an embodiment, the external speaker hole 207 may be implemented as one hole with the microphone hole 203. Although not illustrated, a call receiver hole (not illustrated) may be formed at another portion of the third surface 210C. For example, the call receiver hole may be formed at a portion (e.g., a portion that faces the −y-axis direction) of the third surface 210C, on which the external speaker hole 207 is formed, which portion faces another portion of the third surface 210C. According to various embodiments, the call receiver hole may not be formed at a portion of the third surface 210C, but may be formed by a space (e.g., the space “H” of FIG. 5) between the front plate 202 (or the display 201) and the side bezel structure 218.

The electronic device 200 may include at least one speaker (not illustrated) that is configured to output sound to the outside of the housing 210 through the external speaker hole 207 or the call receiver hole (not illustrated). According to various embodiments, the speaker may include a piezo speaker, from which the speaker hole 207 is omitted.

The sensor module (not illustrated) may generate an electrical signal or a data value that corresponds to an internal operation state of the electronic device 200 or an external environment state. For example, the sensor module 176 may include at least one or more of a proximity sensor, a HRM sensor, a fingerprint sensor, a gesture sensor, a gyro sensor, a barometric pressure sensor, a magnetic sensor, an acceleration sensor, a grip sensor, a color sensor, an infrared (IR) sensor, a biometric sensor, a temperature sensor, a humidity sensor, or an illumination sensor.

The camera modules 205, 212, and 213 may include a first camera module 205 that is exposed through the first surface 210A of the electronic device 200, a second camera module 212 that is exposed through the second surface 210B, and/or a flash 213. Each of the first camera module 205 and the second camera module 212 may include one or more lenses, an image sensor, and/or an image signal processor. The flash 213 may include, for example, a light emitting diode or a xenon lamp.

The first camera module 205 may be visually exposed through a portion of the screen display areas 210A and 210D of the display 201. For example, the first camera module 205 (e.g., a punch hole camera) may be visually exposed to a partial area of the screen display areas 210A and 210D through an opening (not illustrated) that is formed at a portion of the display 201. In various embodiments, the first camera module 205 (e.g., an under-display camera) may be disposed on a rear surface of the display 201, and may not be visually exposed to the screen display areas 210A and 210D.

The second camera module 212 may include a plurality of camera devices (e.g., a dual camera, a triple camera, or a quad camera). However, the second camera module 212 is not necessarily limited to including a plurality of camera devices, and may include only one camera device.

The key input device 217 may be disposed on the third surface 210C of the housing 210. In various embodiments, the electronic device 200 may not include some or all of the key input devices 217, and the key input device 217 that is not included may be implemented in the form of a soft key on the display 201.

The connector hole 208 may accommodate the connector. The connector hole 208 may be disposed on the third surface 210C of the housing 210. For example, the connector hole 208 may be disposed on the third surface 210C to be adjacent to at least a portion of the audio module (e.g., the microphone hole 203 and the speaker hole 207). In various embodiments, the electronic device 200 may include a first connector hole 208 that may accommodate a connector (e.g., a USB connector) for transmitting/receiving electric power and/or data to/from an external electronic device, and/or a second connector hole (e.g., a second connector hole (not illustrated) that may accommodate the connector (e.g., an earphone jack)) for transmitting/receiving an audio signal to/from an external electronic device.

The electronic device 200 may include a light emitting element (not illustrated). For example, the light emitting element (not illustrated) may be disposed on the first surface 210A of the housing 210. The light emitting element (not illustrated) may provide state information of the electronic device 200 in an optical form. In various embodiments, the light emitting element (not illustrated) may provide a light source that is operated in conjunction with the operation of the first camera module 205. For example, the light emitting element (not illustrated) may include an LED, an IR LED, and/or a xenon lamp.

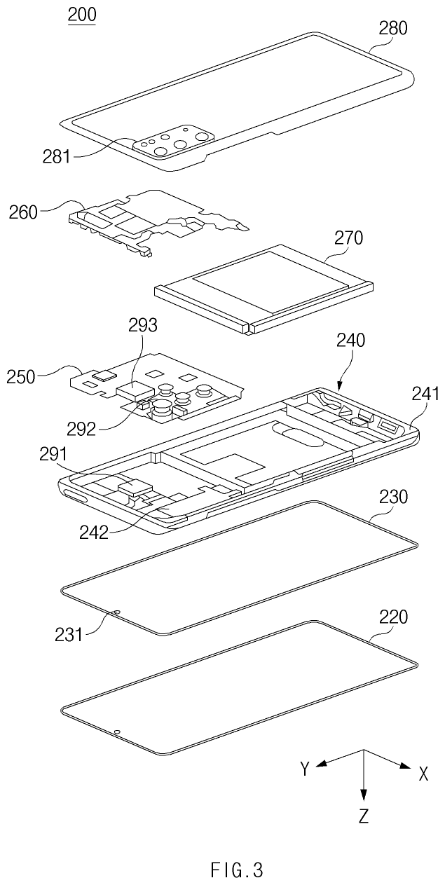

FIG. 3 is an exploded perspective view of an electronic device according to an embodiment.

FIG. 3 is a view illustrating a state, in which the electronic device is disassembled with reference to the rear perspective view of FIG. 2B.

Referring to FIG. 3, an electronic device 200 according to an embodiment may include a front plate 220 (e.g., the front plate 202 of FIG. 2A), a display 230 (e.g., the display 201 of FIG. 2A), a side member 240 (e.g., the side bezel structure 218 of FIG. 2A), a printed circuit board 250, a rear case 260, a battery 270, a rear plate 280 (e.g., the rear plate 211 of FIG. 2B), a camera module 291 and 292, a speaker module 293, and an antenna (not illustrated). In various embodiments, the electronic device 200 may omit at least some of the above components or may further include another component.

At least some of the components of the electronic device 200 illustrated in FIG. 3 may be the same as or similar to the components of the electronic device 200 illustrated in FIGS. 2A and 2B, and hereinafter, repeated descriptions thereof will be omitted.

The front plate 220, the side member 240, and the rear plate 280 may constitute a housing (e.g., the housing 210 of FIGS. 2A and 2B) of the electronic device 200. For example, the housing 210 of the electronic device 200 may refer to a structure, in which a specific accommodation space is formed or defined in an interior thereof by combining the front plate 220, the side member 240, and the rear plate 280.

The front plate 220 and the display 230 may be coupled, directly or indirectly, to the side member 240. For example, the front plate 220 and the display 230 may be disposed under the side member 240 with reference to FIG. 3. The front plate 220 and the display 230 may be located in the +z-axis direction from the side member 240. For example, the display 230 may be coupled under the side member 240, and the front plate 220 may be coupled under the display 230. The front plate 220 may define a portion of an outer surface (or an exterior) of the electronic device 200. The display 230 may be disposed between the front plate 220 and the side member 240 to be located in an interior of the electronic device 200.

The side member 240 may be disposed between the display 230 and the rear plate 280. For example, the side member 240 may be configured to surround the space between the rear plate 280 and the display 230.

The side member 240 may include a frame part 241 that defines a portion of a side surface (e.g., the third surface 210C of FIG. 2A) of the electronic device 200, and a plate part 242 that extends inward from the frame part 241.

The plate part 242 may be disposed in an interior of the frame part 241 to be surrounded by the frame part 241. The plate part 242 may be connected to the frame part 241, or may be integrally formed with the frame part 241. The plate part 242 may be formed of a metal material and/or a non-metal material (e.g., polymer). In an embodiment, the plate part 242 may support other components included in the electronic device 200. For example, at least one of the display 230, the printed circuit board 250, the rear case 260, and the battery 270 may be disposed in the plate part 242. The display 230 may be coupled, directly or indirectly, to one surface (e.g., a surface that faces the +z-axis direction) of the plate part 242, and the printed circuit board 250 may be coupled, directly or indirectly, to a surface (e.g., a surface that faces the −z-axis direction) that faces an opposite direction to the one surface.

A processor (e.g., the processor 120 of FIG. 1), a memory (e.g., the memory 130 of FIG. 1), and/or an interface (e.g., the interface 177 of FIG. 1) may be mounted, directly or indirectly, on the printed circuit board 250. For example, the processor may include one or more of a central processing unit, an application processor, a graphic processing device, an image signal processor, a sensor hub processor, or a communication processor. The memory may include, for example, a volatile memory or a nonvolatile memory. The interface may include, for example, a high definition multimedia interface (HDMI), a universal serial bus (USB) interface, a secure digital (SD) card interface, and/or an audio interface. The interface may electrically or physically connect the electronic device 200 to an external electronic device and may include a USB connector, an SD card/MMC connector, or an audio connector.

The rear case 260 may be disposed between the rear plate 280 and the plate part 242. The rear case 260 may be coupled, directly or indirectly, to the side member 240 to overlap at least a portion of the printed circuit board 250. For example, the rear case 260 may face the plate part 242 with the printed circuit board 250 interposed therebetween.

The battery 270 (e.g., the battery 189 of FIG. 1) may supply power to at least one component of the electronic device 200. For example, a battery 270 may include a non-rechargeable primary battery, a rechargeable secondary battery, or a fuel cell. At least a portion of the battery 270 may be disposed on substantially the same plane as the printed circuit board 250. The battery 270 may be integrally disposed in an interior of the electronic device 200, or may be disposed in the electronic device 200 to be detachable.

The rear plate 280 may be coupled, directly or indirectly, to the side member 240. The rear plate 280 may include a rear camera area 281 for supporting the function/operation of the rear camera (e.g., the second camera module 292). The rear camera area 281 may be formed on a surface (e.g., the rear surface 210B of FIG. 2B) of the rear plate 280. The camera area 281 may be formed such that at least a portion thereof is transparent so that external light is input to the lens of the second camera module 292. At least a portion of the camera area 281 may protrude from the surface of the rear plate 280 by a specific height. However, the disclosure is not limited thereto, and the camera area 281 may define substantially the same plane as the surface of the rear plate 280.

The first camera module 291 (e.g., the first camera module 205 of FIG. 2A) may be disposed in the side member 240 (e.g., the plate part 242) so that the lens may receive external light through a partial area of the front plate 220 (e.g., the front surface 210A of FIG. 2A). For example, the lens of the first camera module 291 may be visually exposed through a partial area of the front plate 220. A front camera area 231 (e.g., an opening area or a light transmission area) corresponding to the first camera module 291 may be formed in the display 230.

The second camera module 292 (e.g., the second camera module 212 of FIG. 2B) may be disposed in the printed circuit board 250 so that the lens may receive external light through the rear camera area 281 of the rear plate 280 (e.g., the rear surface 210B of FIG. 2B) of the electronic device 200. For example, the lens of the second camera module 212 may be visually exposed to the camera area 281. The second camera module 292 may be disposed at at least a portion of an interior space that is formed in the housing (e.g., the housing 210 of FIGS. 2A and 2B) of the electronic device 200, and may be electrically connected to the printed circuit board 250 through a connecting member (e.g., a connector).

The speaker module 293 (e.g., the sound output module 155 of FIG. 1) may be electrically connected to the printed circuit board 250. The speaker module 293 may be supported by, directly or indirectly, a plate part 242 of the side member 240, and may be surrounded by the printed circuit board 250.

An antenna (not illustrated) (e.g., the antenna module 197 of FIG. 1) may be disposed between the rear plate 280 and the battery 270. The antenna (not illustrated) may include, for example, a near field communication (NFC) antenna, an antenna for wireless charging, and/or a magnetic secure transmission (MST) antenna. For example, the antenna (not illustrated) may perform short range communication with an external device or may wirelessly transmit/receive power necessary for charging.

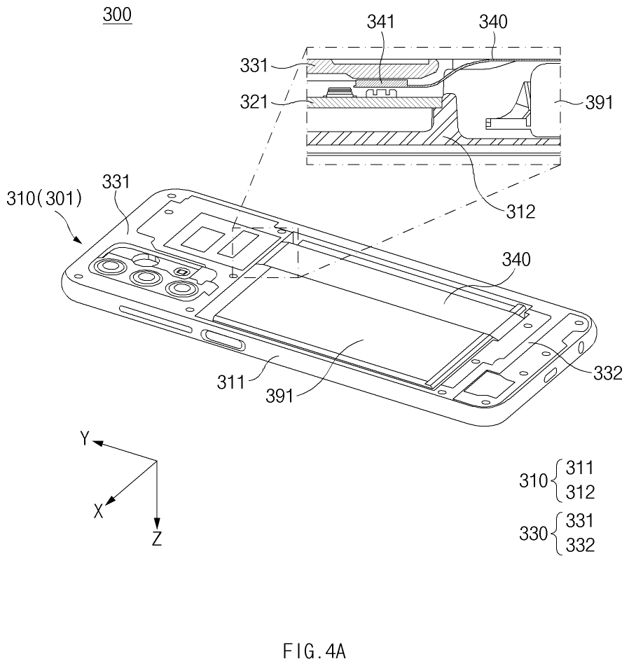

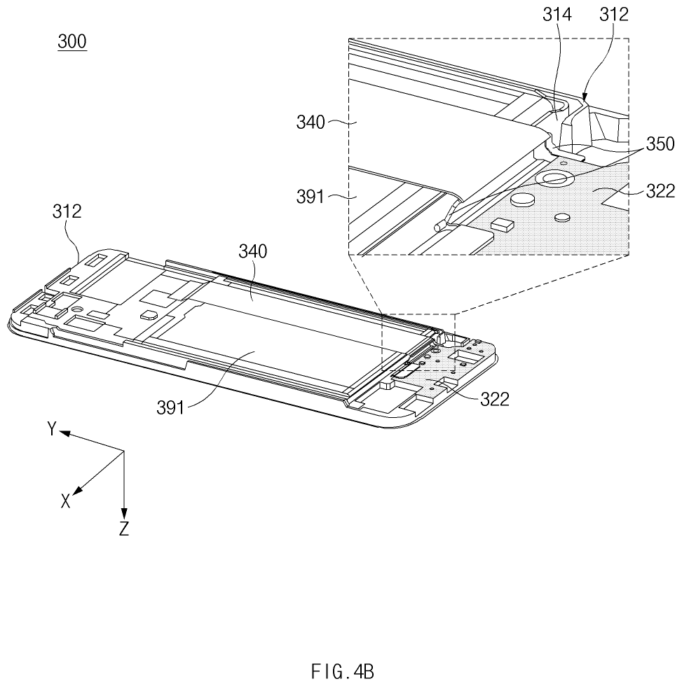

FIG. 4A is a rear perspective view of an electronic device according to an embodiment. FIG. 4B is a rear perspective view of an electronic device according to an embodiment.

FIG. 4B illustrates a state, in which the rear case is separated from the electronic device illustrated in FIG. 4B.

Referring to FIGS. 4A and 4B, an electronic device 300 (e.g., the electronic device 200 of FIG. 3) according to an embodiment may include a side member 310 (e.g., the side member 240 of FIG. 3), a circuit board 320 (e.g., the printed circuit board 250 of FIG. 3), a rear case 330 (e.g., the rear case 260 of FIG. 3), a connecting member 340, an elastic structure 350, and a battery 391 (e.g., the battery 270 of FIG. 3).

At least some of the components of the electronic device 300 illustrated in FIGS. 4A and 4B may be substantially the same as or similar to the components of the electronic device 300 illustrated in FIG. 3, and hereinafter, repeated descriptions thereof will be omitted.

The side member 310 may constitute the housing 301 (e.g., the housing 210 of FIGS. 2A and 2B) of the electronic device 300, or may be a portion of the housing 301. For example, the housing 301 of the electronic device 300 may be provided in a structure, in which the side member 310, the front plate (e.g., the front plate 220 of FIG. 3) and the rear plate (e.g., the rear plate 280 of FIG. 3) are coupled to each other. For example, FIG. 4A may be a view, in which the front plate and the rear plate of the electronic device 300 are omitted and only the side member 310 is illustrated.

The side member 310 may include a plate part 312 (e.g., a plate part 242 of FIG. 3), in which the circuit board 320, the battery 391, and the elastic structure 350 are disposed, and a frame part 311 (e.g., a frame part 241 of FIG. 3) that surrounds a periphery of the plate part 312. The rear case 330 may be coupled to the plate part 312. For example, the circuit board 320, the battery 391, and the elastic structure 350 may be disposed on one side (e.g., the −z-axis direction) of the plate part 312, and the rear case 330 may be coupled to overlap the circuit board 320. The plate part 312 may include a sidewall 314 that forms or defines a space, in which the battery 391 is accommodated. For example, the sidewall 314 may extend to surround a periphery of the battery 391. A portion (e.g., a portion that faces the −y-axis direction) of the sidewall 314 may face the elastic structure 350. According to various embodiments, the plate part 312 may be referred to as a front case. FIG. 4B may be a view, in which a frame part 311 of the side member 310 is omitted.

The circuit board 320 may be disposed in the plate part 312 of the side member 310. For example, the circuit board 320 may be coupled to the plate part 312 through various fastening means (e.g., screws). For example, the circuit board 320 may be a printed circuit board (PCB). The circuit board 320 may include a first circuit board 321 that is located at an upper end (e.g., the +y-axis direction) of the electronic device 300, and a second circuit board 322 that is located at a lower end (e.g., the −y-axis direction) of the electronic device 300. For example, the first circuit board 321 may be located in the +y-axis direction with respect to the battery 391, and the second circuit board 322 may be located in the −y-axis direction with respect to the battery 391. The first circuit board 321 may be referenced as a printed circuit board (e.g., the printed circuit board 250 of FIG. 3) of the electronic device 300 illustrated in FIG. 3. The first circuit board 321 and the second circuit board 322 may be electrically connected to each other through a connecting member 340. According to various embodiments, the first circuit board 321 may be referred to as an upper PCB or a main PCB, and the second circuit board 322 may be referred to as a lower PCB or a sub-PCB.

The rear case 330 may be coupled to the plate part 312 of the side member 310. For example, the rear case 330 may be coupled to the plate part 312 to cover the circuit board 320. The rear case 330 may overlap the circuit board 320 with respect to the rear ward direction (e.g., the −z-axis direction) of the electronic device 300. The rear case 330 may include a first rear case 331 that is located at an upper end (e.g., the +y-axis direction) of the electronic device 300, and a second rear case 332 that is located at a lower end (e.g., the −y-axis direction) of the electronic device 300. For example, the first rear case 331 may be located in the +y-axis direction with respect to the battery 391, and the second rear case 332 may be located in the −y-axis direction with respect to the battery 391. The first rear case 331 may be referenced as a rear case (e.g., the rear case 260 of FIG. 3) of the electronic device 300 illustrated in FIG. 3. In various embodiments, the first rear case 331 and the second rear case 332 may be connected to each other, and may be integrally formed.

The first rear case 331 may face at least a portion of the first circuit board 321, and the second rear case 332 may face at least a portion of the second circuit board 322. For example, the first rear case 331 may be coupled to the plate part 312 to cover the first circuit board 321, and the second rear case 332 may be coupled to the plate part 312 to cover the second circuit board 322. The first rear case 331 may overlap the first circuit board 321 in a rearward direction of the electronic device 300. For example, the first circuit board 321 may be disposed in a space between a partial area of the plate part 312 and the first rear case. The second rear case 332 may overlap the second circuit board 322 and the elastic structure 350 in the rearward direction of the electronic device 300. For example, the elastic structure 350 and the second circuit board 322 may be disposed in a space between a partial area of the plate part 312 and the second rear case 332. When the rear case 330 is viewed from above with reference to FIG. 4A, the first circuit board 321 and one end of the connecting member 340 may be located under the first rear case 331, and the elastic structure 350, the second circuit board 322, and an opposite end of the connecting member 340 may be located under the second rear case 332.

The connecting member 340 may electrically connect the first circuit board 321 and the second circuit board 322. One end (e.g., an end in the +y-axis direction) of the connecting member 340 may be connected to the first circuit board 321, and an opposite end (e.g., an end in the −y-axis direction) of the connecting member 340 may be connected to the second circuit board 322. For example, opposite ends of the connecting member 340 may be formed as connectors 341. The connecting member 340 may extend in the lengthwise direction (e.g., the y-axis direction) of the electronic device 300, and may cross the battery 391. The connecting member 340 may extend from the first circuit board 321 located on one side (e.g., the +y-axis direction) of the battery 391 to the second circuit board 322 located on an opposite side (e.g., the −y-axis direction) of the battery 391.

The connecting member 340 may be formed to have a margin of a specific length to prevent or reduce separation from the first circuit board 321 and the second circuit board 322. The connecting member 340 may be connected to the first circuit board 321 and the second circuit board 322 while at least a portion thereof is bent. The connecting member 340 may be formed of a conductive material having flexibility, and may be moved in a specific range in the lengthwise direction of the connecting member 340 by shaking the electronic device 300 or by an external force applied to the electronic device 300. For example, the connecting member 340 may include a flexible printed circuit board (FPCB). At least a portion of the connecting member 340 may be supported, directly or indirectly, by the elastic structure 350 coupled to the plate part 312, and the movement of the connecting member 340 may be guided by the elastic driving of the elastic structure 350.

The elastic structure 350 may be coupled, directly or indirectly, to the plate part 312. The elastic structure 350 may support a partial section of the connecting member 340. The elastic structure 350 may guides the movement and/or deformation of the connecting member 340 by elastically driving some components with an external force, and may formalize the bent shape of the connecting member 340. Hereinafter, the structure and driving of the elastic structure 350 will be described in detail with reference to FIGS. 5, 6, and 7.

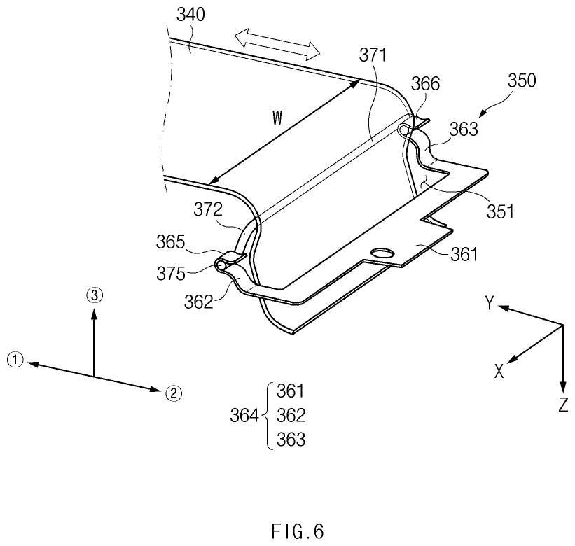

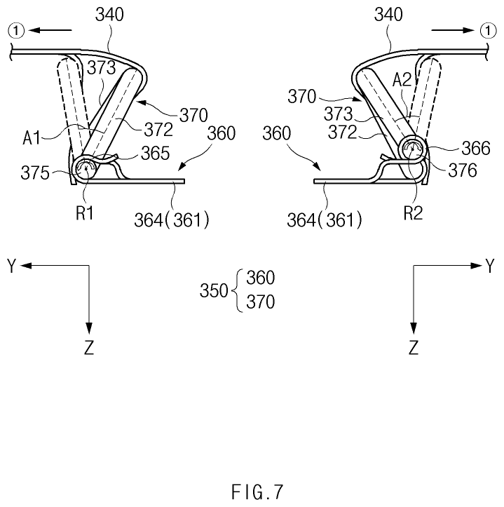

FIG. 5 is a view illustrating an elastic structure of an electronic device according to an embodiment. FIG. 6 is a view illustrating a connecting member and an elastic structure of an electronic device according to an embodiment. FIG. 7 is a view illustrating driving of an elastic structure of an electronic device according to an embodiment.

FIG. 5 illustrates a front view, a left side view, and a right side view of the elastic structure. For example, FIG. 5 illustrates a basic state of the elastic structure, to which an external force is not illustrated. FIG. 6 is a view, in which other components than the connecting member and the elastic structure in FIG. 4B are omitted. FIG. 7 is a view illustrating an operation of deforming the elastic structure in correspondence to an external force applied to the elastic structure. For example, FIG. 7 illustrates views that illustrate an operation of deforming the elastic structure from a basic state by an external force in FIG. 7, when viewed from a left side and a right side.

Referring to FIGS. 5 and 6, the elastic structure 350 of the electronic device 300 according to an embodiment may include a holder 360, and a rod 370 that is coupled, directly or indirectly, to the holder 360 to be rotatable.

The holder 360 may be coupled, directly or indirectly, to a side member (e.g., the side member 310 of FIGS. 4A and 4B) of the electronic device 300. The holder 360 may include a first base part 364, a first coupling part 365 that extends from one end of the first base part 364, and a second coupling part 366 that extends from an opposite end of the first base part 364. The first base part 364 may be coupled to a plate part (e.g., the plate part 312 of FIG. 4B). Opposite ends of the rod 370 may be coupled to the first coupling part 365 and the second coupling part 366 to be rotatable, respectively. For example, the first extension part 375 of the rod 370 may be coupled to the first coupling part 365 to be rotatable, and the second extension part 376 of the rod 370 may be coupled to the second coupling part 366 to be rotatable.

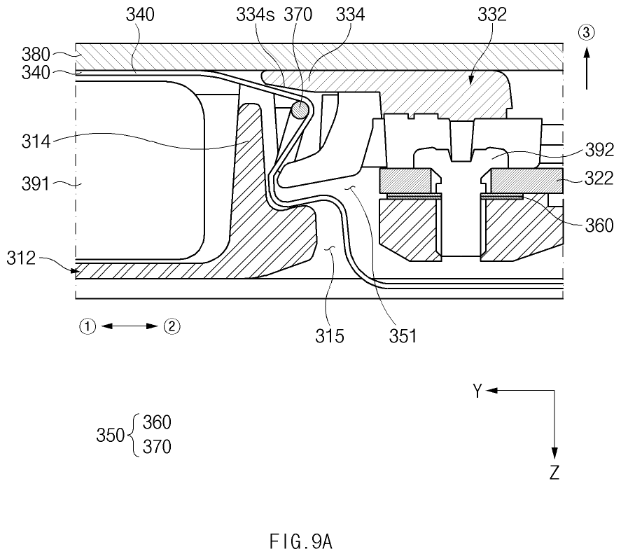

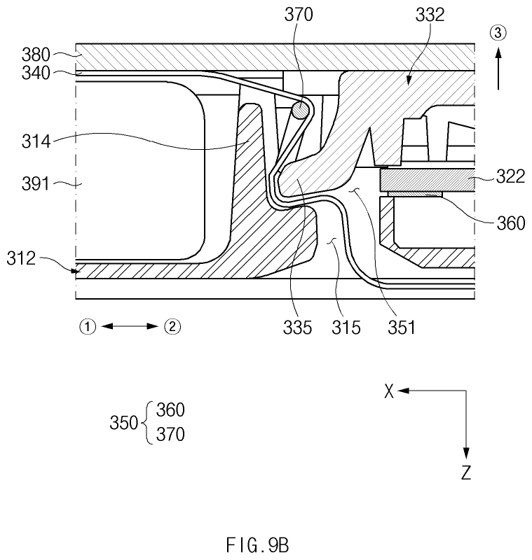

The first base part 364 of the holder 360 may include a first portion 361 that is seated on, attached to, or coupled to the plate part 312, a second portion 362 that connects the first portion 361 and the first coupling part 365, and a third portion 363 that connects the first portion 361 and the second coupling part 366. The first portion 361 may be parallel to one surface of the plate part 312, and the second portion 362 and the third portion 363 may extend from opposite ends of the first portion 361. For example, the first portion 361 of the first base part 364 may be parallel to the second circuit board (e.g., the second circuit board 322 of FIG. 9A) or the rear plate (e.g., the rear plate 380 of FIG. 9A) (e.g., see FIG. 9A). For example, the first coupling part 365 may extend from the second portion 362 of the first base part 364, and the second coupling part 366 may extend from the third portion 363 of the first base part 364.

The coupling parts 365 and 366 of the holder 360 may have elasticity to apply a specific pre-pressure to the extension parts 375 and 376 of the rod 370. The first coupling part 365 and the second coupling part 366 may be bent in correspondence to the shapes of the first extension part 375 and the second extension part 376, and the first extension part 375 and the second extension part 376 may be elastically fitted into the interiors of the first coupling part 365 and the second coupling part 366, respectively. For example, recesses of shapes corresponding to the first extension part 375 and the second extension part 376 may be formed in the first coupling part 365 and the second coupling part 366, and the first extension part 375 and the second extension part 376 may be partially inserted into the corresponding recesses of the first coupling part 365 and the second coupling part 366, respectively.

The holder 360 may be formed in a shape, in which the first coupling part 365 and the second coupling part 366 are located at different heights from the first base part 364. The first coupling part 365 and the second coupling part 366 may be formed at positions that are spaced apart from the first portion 361 of the first base part 364 by the same distance in the first direction \textcircled{1}. The first direction \textcircled{1} may be a direction (e.g., the +y-axis direction) that is parallel to the first portion 361, and in which the coupling parts 365 and 366 extend from the first base part 364. For example, the distance between the first portion 361 and the first coupling part 365 with respect to the first direction \textcircled{1} may be the same as the distance between the first portion 361 and the second coupling part 366. For example, the first coupling part 365 and the second coupling part 366 may be spaced apart from a first periphery of the first base part 364 (e.g., the first portion 361) by the same distance in the first direction \textcircled{1}. The first periphery is a periphery of the first port 361, which faces the second direction \textcircled{2} (e.g., the −y-axis direction) that is opposite to the first direction \textcircled{1}. The first coupling part 365 and the second coupling part 366 may be formed at positions that are spaced apart from the first portion 361 of the first base part 364 by different distances in a third direction \textcircled{3} that is perpendicular to the first direction \textcircled{1}. For example, the third direction \textcircled{3} may be a direction (e.g., the −z-axis direction) that is substantially perpendicular to one surface of the first port 361, and the third direction \textcircled{3} may be perpendicular to the first direction \textcircled{1} and the second direction \textcircled{2}. The first coupling part 365 may be spaced apart from the first portion 361 by a second distance in the third direction \textcircled{3}, and the second coupling part 366 may be spaced apart from the first portion 361 by a second distance that is greater than the first distance in the third direction \textcircled{3}. As the first extension part 375 and the second extension part 376 are coupled to be first coupling part 365 and the second coupling part 366 to be rotatable, respectively, a first rotation axis R1 and a second rotation axis R2 of opposite ends of the rod 370 may be arranged in parallel with respect to the third direction \textcircled{3}, and a height difference (e.g., a difference between a first height H1 and a second height H2 of FIG. 7) may occur along the third direction \textcircled{3} between the first rotation axis R1 and the second rotation axis R2.

Opposite ends of the rod 370 may be coupled to the holder 360 to be rotatable, respectively, and may have a specific elasticity. The rod 370 may include a second base part 374, a first extension part 375 that extends from one end of the second base part 374, and a second extension part 376 that extends from an opposite end of the second base part 374. The rod 370 may be formed or provided in a shape, in which the first extension part 375 and the second extension part 376 may be coupled to the first coupling part 365 and the second coupling part 366 of the holder 360, respectively, in correspondence to the shape of the holder 360. The first extension part 375 may define or form the first rotation axis R1 as it is coupled to the first coupling part 365 of the holder 360 to be rotatable. The second extension part 376 may define or form the second rotation axis R2 as it is coupled to the second coupling part 366 of the holder 360 to be rotatable. For example, the first rotation axis R1 of the rod 370 may be an imaginary straight line that passes through the center of the first extension part 375, and the first rotation axis R1 of the rod 370 may be an imaginary straight line that passes through the center of the second extension part 376.

The second base part 374 of the rod 370 may include a fourth portion 371 that extends long in the direction of the rotation axes R1 and R2, a fifth portion 372 that connects the fourth portion 371 to the first extension part 375, and a sixth portion 373 that connects the fourth portion 371 to the second extension part 376. For example, the first extension part 375 may extend from the fifth portion 372 substantially perpendicularly thereto. The second extension part 376 may extend from the sixth portion 373 substantially perpendicularly thereto. The fourth portion 371 of the second base part 374 may extend parallel to a width “W” direction (e.g., the x-axis direction) of the connecting member 340. Each of the fifth and sixth portions 372 and 373 may be substantially perpendicular to the fourth portion 371, but may extend in different lengths and different directions from opposite ends of the fourth portion 371. The fifth portion 372 and the sixth portion 373 may extend in correspondence to the height difference between the first coupling part 365 and the second coupling part 366, into which the first extension part 375 and the second extension part 376 are inserted.

The rod 370 may be formed in a shape, in which the first extension part 375 and the second extension part 376 are not aligned with and misaligned from each other in a direction (directions of the rotation axes R1 and R2 or the x-axis direction), in which the fourth portion 371 of the second base part 374 extends. As illustrated in FIG. 5, in a basic state, in which no external force is applied to the elastic structure 350, the first extension part 375 and the second extension part 376 may be formed at positions that are spaced apart from the fourth portion 371 of the second base part 374 by the same distance in the first direction \textcircled{1}. For example, the distance between the fourth portion 371 and the first extension part 375 with respect to the first direction \textcircled{1} may be the same as the distance between the fourth portion 371 and the second extension part 376. For example, the first extension part 375 and the second extension part 376 may be spaced apart from the fourth portion 371 by the same distance in the first direction \textcircled{1}. As illustrated in FIG. 5, in a basic state, in which no external force is applied to the elastic structure 350, the first extension part 375 and the second extension part 376 may be formed at positions that are spaced apart from the fourth portion 371 of the second base part 374 by different distances in an opposite direction to the third direction \textcircled{3}. The first extension part 375 may be spaced apart from the fourth portion 371 by a third distance in an opposite direction to the third direction \textcircled{3}, and the second extension part 376 may be spaced apart from the first portion 361 in an opposite direction to the third direction \textcircled{3} by a fourth distance that is smaller than the third distance. For example, the distances between the fourth portion 371, the first extension part 375, and the second extension part 376 may be the distances between the central axes thereof. As the first extension part 375 and the second extension part 376 of the rod 370 are coupled to the first coupling part 365 and the second coupling part 366 of the holder 360 to be rotatable, respectively, the first rotation axis R1 and the second rotation axis R2 may be located on an imaginary line “L” that is parallel to the third direction \textcircled{3}, and the second rotation axis R2 may be spaced apart from the first rotation axis R1 by a specific distance (e.g., a difference between the first height H1 and the second height H2) in the third direction \textcircled{3}.

The connecting member 340 may be connected to the elastic structure 350. The connecting member 340 may extend across a space between the rod 370 and the holder 360. For example, an opening 351 may be formed between the holder 360 and the rod 370 of the elastic structure 350. The connecting member 340 may pass through the opening 351 of the elastic structure 350. For example, at least a portion of the connecting member 340 may contact the rod 370 (e.g., the fourth portion 371 of the rod 370), and may extend through the opening 351. With reference to FIG. 6, the connecting member 340 may be connected to or assembled in the elastic structure 350 such that the rod 370 is located at a lower portion (e.g., the third direction \textcircled{3}) of a portion of the connecting member 340, and the holder is located at an upper portion (e.g., the third direction \textcircled{3} of a portion of the connecting member 340.

Referring to FIGS. 5, 6, and 7, the elastic structure 350 may control and optimize the movement of the connecting member 340 by using the torsional elasticity of the rod 370. For example, the elastic structure 350 may be a spring structure that uses a repulsive force generated when the rod 370 is twisted by an external force. When an external force is applied to the elastic structure 350 in a basic state, opposite ends of the rod 370 may be rotated with respect to the holder 360 around the first rotation axis R1 and the second rotation axis R2, respectively, and a torsional displacement (or a torsional deformation) may occur as the rod 370 is twisted due to the height difference between the first rotation axis R1 and the second rotation axis R2. The rod 370 in a twisted state may have a restoring force to return to its original state, and the elastic structure 350 may return to a basic state by the restoring force of the rod 370 when the applied external force is removed. In a state, in which no external force is applied to the electronic device 300, the connecting member 340 may be pulled in the second direction \textcircled{2} by the elastic structure 350 having a restoring force for maintaining a basic state, and may be bent in a specific shape in an interior of the electronic device 300. For example, when an external force that is greater than the restoring force of the elastic structure 350 is not applied to the electronic device 300, the connecting member 340 and the elastic structure 350 may be maintain in a state illustrated in FIG. 6 or a state indicated by a dotted line in FIG. 7.

The rod 370 may be twisted as opposite ends thereof are rotated around the first rotation axis R1 and the second rotation axis R2 located at different heights, respectively. For example, the first rotation axis R1 and the second rotation axis R2 may be aligned on the same line “L” with respect to the third direction \textcircled{3}, but may be spaced apart from each other. The first rotation axis R1 may be located at a first height H1 in the third direction \textcircled{3} from the first portion 361 of the first base part 364. The second rotation axis R2 may be located at a second height H2 that is greater than the first height H1 in the third direction \textcircled{3} from the first portion 361 of the first base part 364. The first rotation axis R1 and the second rotation axis R2 may be spaced apart from each other by the difference between the first height H1 and the second height H2 on the imaging line “L” that is parallel to the third direction \textcircled{3}.

Referring to FIGS. 6 and 7, as the connecting member 340 is moved in the first direction \textcircled{1} or the second direction \textcircled{2}, an external force may be applied to the elastic structure 350 or the applied external force may be removed. When the connecting member 340 is moved in the first direction \textcircled{1} as an external force is applied to the electronic device 300, an external force may be applied to the rod 370 of the elastic structure 350 in a basic state in the first direction \textcircled{1} by the connecting member 340, and the rod 370 may be twisted while opposite ends 375 and 376 thereof are rotated in a first rotational direction (e.g., a direction that becomes more distant from the first base part 364 of the holder 360) around the first rotation axis R1 and the second rotation axis R2. When the connecting member 340 is moved in the second direction \textcircled{2} as the external force applied to the electronic device 300 is removed, the elastic structure 350 may return to the basic state while opposite ends 375 and 376 of the rod 370 in a twisted state are rotated with respect to the holder 360 in a second rotational direction (e.g., a direction that becomes closer to the first base part 364 of the holder 360) that is opposite to the first rotational direction around the first rotation axis R1 and the second rotation axis R2. For example, in the basic state of the elastic structure 350, that is, when an external force is not applied to the elastic structure 350, the elastic structure 350 may have a pattern or a shape that is maintained basically, and when the external force applied to the elastic structure 350 is smaller than a magnitude of a force, by which a torsional displacement may occur in the rod 370 (e.g., the external force is smaller than a torsional repulsive force of the rod 370), the elastic structure 350 may be maintained in the basic state.

When the rod 370 is rotated in the first rotational direction as an external force is applied to the elastic structure 350 in the basic state in the first direction \textcircled{1}, an angle, by which the fifth portion 372 connected to the first extension part 375 is rotated, and an angle, by which the sixth portion 373 connected to the second extension part 376 is rotated, may be different due to the height difference between the first rotation axis R1 and the second rotation axis R2. For example, in an operation of moving the connecting member 340 in the first direction \textcircled{1} by a specific distance, the fifth portion 372 connected to the first extension part 375 rotated around the first rotation axis R1 may be rotated in the first rotational direction by a first angle A1, and the sixth portion 373 connected to the second extension part 376 rotated around the second rotation axis R2 may be rotated in the first rotational direction by a second angle A2 that is greater than the first angle A1. As the fifth portion 372 and the sixth portion 373 of the second base part 374 are rotated at different angles, a torsional displacement may occur in the rod 370.

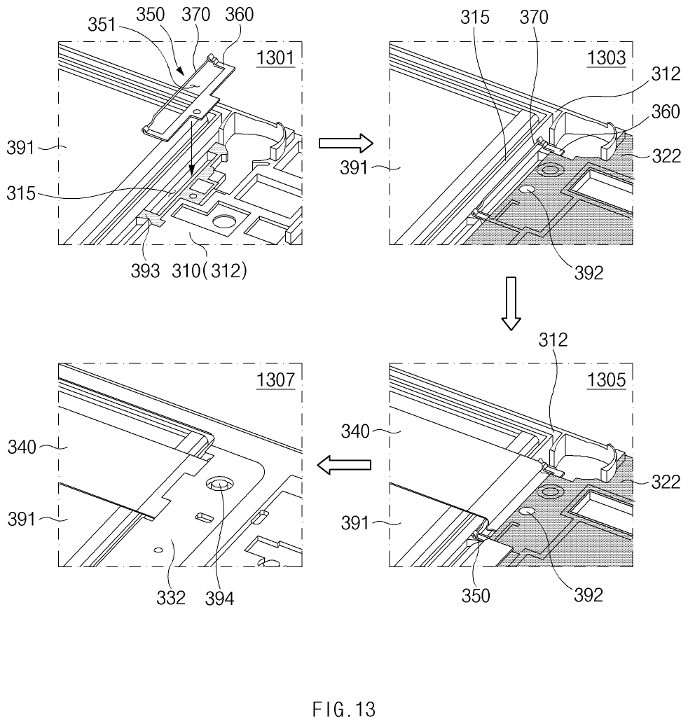

The structure of the elastic structure 350 illustrated in FIGS. 5, 6, and 7 is illustrated by way of example, and the structure of the elastic structure 350 according to embodiments disclosed in the disclosure is not limited to those of FIGS. 5, 6, and 7, and may be implemented in various forms. Various embodiments of the elastic structure 350 are described below with reference to FIGS. 13 to 18.

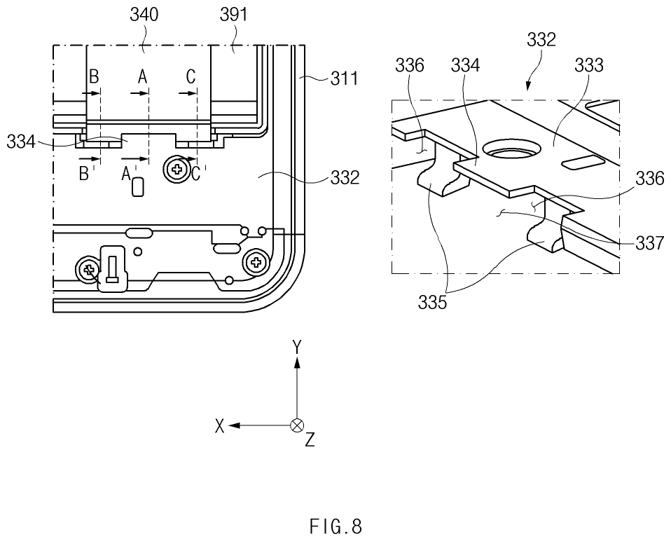

FIG. 8 is a view illustrating a rear case and a connecting member of an electronic device according to an embodiment. FIG. 9A is a cross-sectional view of an electronic device according to an embodiment. FIG. 9B is a cross-sectional view of an electronic device according to an embodiment.

FIG. 8 illustrates a plan view of a portion of an electronic device, in which the connecting member and the rear case are disposed, and a view illustrating a shape of the rear case. FIG. 9A is a view illustrating cross section A-A′ of the electronic device according to an embodiment illustrated in FIG. 8. FIG. 9B is a view illustrating cross section B-B′ and cross-section C-C′ of the electronic device according to an embodiment illustrated in FIG. 8.

Referring to FIGS. 8, 9A, and 9B, an electronic device 300 according to an embodiment may include a side member 310, a second circuit board 322, a second rear case 332, a connecting member 340, an elastic structure 350, a rear plate 380 (e.g., the rear plate 380 of FIG. 3), and a battery 391.

At least some of the components of the electronic device 300 illustrated in FIGS. 8, 9A, and 9B may be substantially the same as or similar to the components of the electronic device 300 illustrated in FIGS. 4A and 4B and/or the elastic structure 350 illustrated in FIGS. 5 to 7, and repeated descriptions thereof will be omitted. For example, FIGS. 9A and 9B may be views illustrating a cross section of the electronic device 300 when the elastic structure 350 is in a basic state (e.g., the state of the elastic structure 350 illustrated in FIGS. 5 and 6).

The side member 310 may include a frame part 311 and a plate part 312. A second circuit board 322, a second rear case 332, and an elastic structure 350 may be coupled to the plate part 312. A through-hole 315 (e.g., a through-hole 315 of FIG. 13), through which the connecting member 340 passes, may be formed in the plate part 312. For example, the through-hole 315 may be formed on one side of a portion, at which the second circuit board 322 and the elastic structure 350 are coupled to each other. The connecting member 340 may extend from a space between the plate part 312 and the rear plate 380 to a space between the plate part 312 and the display (e.g., the display 230 of FIG. 3) through an opening (e.g., the opening 351 of FIG. 6) of the elastic structure 350 and the through-hole 315. The side member 310 may include a sidewall 314 (e.g., the sidewall 314 of FIG. 4B) that defines a space, in which the battery 391 is accommodated, and a portion (e.g., a portion that faces the −y-axis direction) of the sidewall 314 may face the elastic structure 350. A portion of the sidewall 314, which faces the elastic structure 350, may control or limit a driving range (e.g., a rotation range of the rod 370) of the elastic structure 350 while contacting the rod 370.

The second circuit board 322 and the elastic structure 350 may be coupled, directly or indirectly, to the plate part 312. The second circuit board 322 and the elastic structure 350 may be disposed between the plate part 312 and the second rear case 332. The second circuit board 322 and the holder 360 of the elastic structure 350 may be fixed to the plate part 312 through the first fixing member 392. For example, the holder 360 may be disposed between the plate part 312 and the second circuit board 322, and the first fixing member 392 may sequentially pass through the second circuit board 322 and the holder 360 to be fastened to the plate part 312. The first fixing member 392 may be a screw, but the disclosure is not limited thereto.

The second rear case 332 may be coupled to the plate part 312 to cover the second circuit board 322 and the elastic structure 350. The second rear case 332 may include a first protruding part 334 and a second protruding part 335 for guiding (or controlling) the movement and/or the shape of the connecting member 340.

The first protruding part 334 of the second rear case 332 may protrude in the first direction \textcircled{1}from the body part 333 of the rear case 330 to be located between the elastic structure 350 and the rear plate 380. The first protruding part 334 may be located in the third direction \textcircled{3} with respect to the elastic structure 350, and may cover a partial area of the connecting member 340 connected to the elastic structure 350. For example, when the second rear case 332 is viewed from a top with reference to FIG. 8, a portion of the connecting member 340 may be disposed under the first protruding part 334. The first protruding part 334 may be spaced apart from the elastic structure 350 so as not to collide with the rod 370 when the rod 370 of the elastic structure 350 is rotated. For example, a space, in which the connecting member 340 may be moved, may be formed or defined between the first protruding part 334 and the rod 370. The first protruding part 334 may be formed as a surface 334s, in which a surface that faces the connecting member 340 is inclined at a specific inclination. The first protruding part 334 may prevent or limit the connecting member 340 from colliding with the rear plate 380 or pushing the rear plate 380 in the third direction \textcircled{3} when the connecting member 340 is moved in the first direction \textcircled{1} or the second direction \textcircled{2} by the external force applied to the electronic device 300. For example, the connecting member 340 may be moved along the inclined surface 334s of the first protruding part 334.

The second protruding part 335 of the second rear case 332 may protrude in the first direction \textcircled{1} from the body part 333 of the rear case 330 to be partially located between the rod 370 of the elastic structure 350 and the plate part 312. For example, at least a portion of the second protruding part 335 may be disposed within the opening 351 of the elastic structure 350. The second protruding part 335 may be located to face the plate part 312, and a portion of the connecting member 340 may be disposed in a space between the second protruding part 335 and the plate part 312. The second protruding part 335 may formalize a shape, in which the connecting member 340 is bent. For example, the connecting member 340 may be bent into a specific shape while extending along a spacing space between the second protruding part 335 and the plate part 312. The second protruding part 335 may guide or control the movement of the connecting member 340 so that the connecting member 340 is not rapidly dragged when the connecting member 340 is moved in the first direction \textcircled{1}. For example, as the connecting member 340 is moved between the second protruding part 335 and the plate part 312 while being bent in correspondence to the shape of the second protruding part 335, a rapid movement thereof may be prevented or reduced.

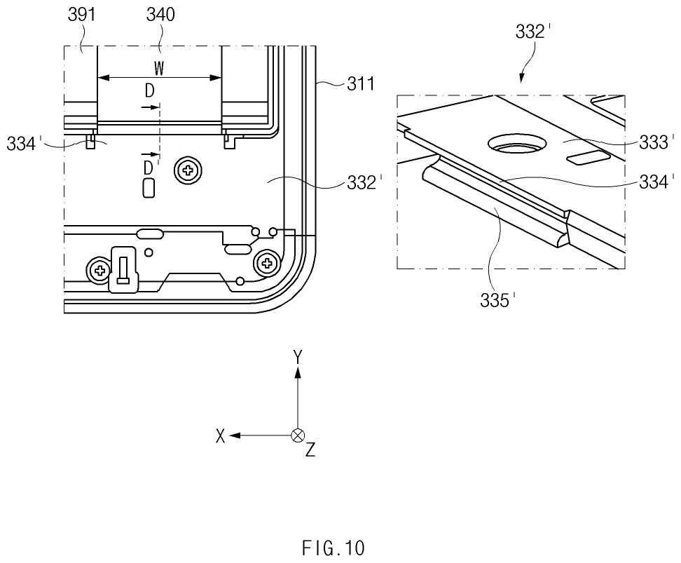

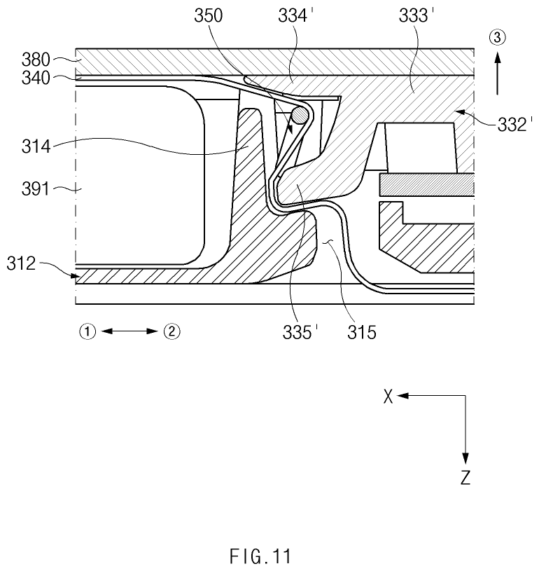

According to the embodiment illustrated in FIG. 8, the second rear case 332 may have a first cutaway portion 336 formed on opposite sides of the first protruding part 334, and a second cutaway portion 337 may be formed between the pair of second protruding parts 335. For example, the second protruding part 335 may overlap the first cutaway portion 336 on opposite sides of the first protruding part 334 in the third direction \textcircled{3}, and the first protruding part 334 may overlap the second cutaway portion 337 between the second protruding parts 335 in the third direction \textcircled{3}. The embodiment illustrated in FIG. 8 relates to the second rear case 332 manufactured through an injection process using a mold, and the cutaway portions 336 and 337 may be spaces for removing the mold in the process of separating or extracting the injection-molded product from the mold. When the second rear case 332 is manufactured through the injection process using the mold, production costs may be reduced. The manufacturing method and the shape of the second rear case 332 are not limited to the embodiment illustrated in FIG. 8, and according to various embodiments, the first protruding part 334 and the second protruding part 335 may extend without the cutaway portions 336 and 337 (e.g., see FIGS. 10 and 11).

The connecting member 340 may be bent into a specific shape while a portion thereof is supported by, directly or indirectly, the elastic structure 350. A first end (e.g., an end in the +y-axis direction and an end in the first direction \textcircled{1} of the connecting member 340 may be connected to the first circuit board (e.g., the first circuit board 321 of FIG. 4A) at an upper end of the electronic device 300. A central portion (e.g., the remaining portion except opposite ends thereof) of the connecting member 340 may extend from the first end in the second direction \textcircled{2} across the battery 391 such that at least a portion thereof is supported by, directly or indirectly, the elastic structure 350. A second end (e.g., an end in the −y-axis direction or an end in the second direction \textcircled{2} of the connecting member 340, which faces an opposite side to the first end may be connected to the second circuit board 322 at a lower end of the electronic device 300.

A central portion of the connecting member 340 may extend through the opening 351 of the elastic structure 350 and the through-hole 315 of the plate part 312 such that a portion thereof is located above the plate part 312 (e.g., in the third direction \textcircled{3} with respect to the plate part 312) and another portion thereof is located under the plate part 312 (e.g., an opposite direction to the third direction \textcircled{3} with respect to the plate part 312). For example, at least a partial section of the central portion of the connecting member 340 may extend sequentially across a space between the battery 391 and the rear plate 380, a space between the first protruding part 334 of the second rear case 332 and the rod 370, the opening 351 of the elastic structure 350, a space between the side wall 314 of the plate part 312 and the second protruding part 335 of the second rear case 332, and the through-hole 315 of the plate part 312.

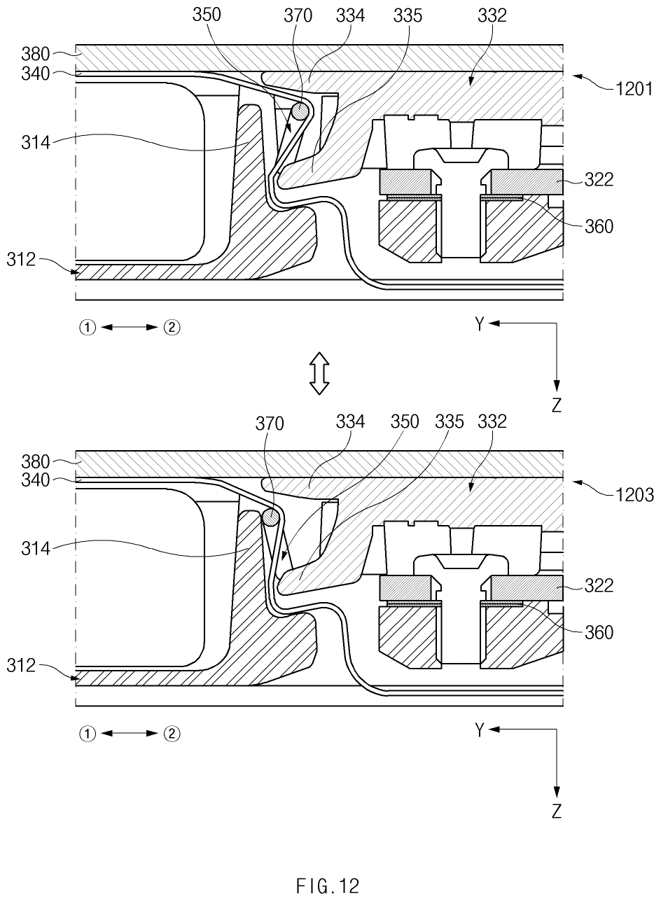

The connecting member 340 may be maintained in a state, in which it is bent in a specific shape, in an interior of the electronic device 300 by the elastic structure 350 in a basic state. For example, when no external force is applied to the electronic device 300, the elastic structure 350 may be maintained in the basic state, and a partial area of the connecting member 340 may be supported while contacting the rod of the elastic structure 350, the elastic structure 350 may be bent into a shape, in which it is located between the first protruding part 334 of the second rear case 332 and the elastic structure 350. According to an example embodiment, when an external force is applied to the electronic device 300 and then is removed, the connecting member 340 may be automatically restored to the bent shape before the external force is applied through an operation of the elastic structure 350. The operation of the elastic structure 350 and the movement of the connecting member 340 will be described in more detail with reference to FIG. 12.

The rear plate 380 may define a rear surface of the electronic device 300. The rear plate 380 may be coupled to the side member 310 to cover the battery 391 and the rear case (e.g., the second rear case 332 and the first rear case 331 of FIG. 4A).

FIG. 10 is a view illustrating a rear case and a connecting member of an electronic device according to an embodiment. FIG. 11 is a cross-sectional view of an electronic device according to an embodiment.

FIG. 10 illustrates a plan view of a portion of an electronic device, in which the connecting member and the rear case are disposed, and a view illustrating a shape of the rear case. FIG. 11 is a view illustrating cross section D-D′ of the electronic device according to an embodiment illustrated in FIG. 10.

Referring to FIGS. 10 and 11, an electronic device 300 according to an embodiment may include a side member 310, a second circuit board 322, a second rear case 332′, a connecting member 340, an elastic structure 350, a rear plate 380, and a battery 391.

The embodiment illustrated in FIGS. 10 and 11 relates to a second rear case 332′ having a shape that is different from that of the second rear case 332 according to the embodiments of FIGS. 8, 9A, and 9B, and hereinafter, a repeated description thereof will be omitted, and their differences will be mainly described.

Unlike in the second rear case 332 according to the first embodiment illustrated in FIGS. 8, 9A, and 9B, in the second rear case 332′ according to the second embodiment illustrated in FIGS. 10 and 11, cutaway portions (e.g., the cutaway portions 336 and 337 of FIG. 8) may not be formed in the first protruding part 334′ and the second protruding part 335′.

The second rear case 332′ may be formed in a shape, in which the first protruding part 334′ and the second protruding part 335′ continuously extend in a width “W” direction of the connecting member 340 in correspondence to the width “W” of the connecting member 340. For example, the first protruding part 334′ may continuously cover a partial area of the connecting member 340 disposed under the first protruding part 334′. For example, the second protruding part 335′ may continuously support a partial area of the connecting member 340 that extends into a space between the second protruding part 335′ and the plate part 312. The second rear case 332′ according to the second embodiment may be manufactured through computer numerical control (CNC) processing, but the disclosure is not limited thereto.

Compared to the second rear case 332 according to the first embodiment, the second rear case 332′ according to the second embodiment may more effectively provide a function of preventing or reducing the connecting member 340 from pushing out the rear plate 380 or colliding with the rear plate 380 through the first protruding part 334′ because an area of the first protruding part 334′, which overlaps the connecting member 340, is relatively large. Compared to the second rear case 332 according to the first embodiment, the second rear case 332′ according to the second embodiment may more effectively provide a function of formalizing a bent shape of a portion of the connecting member 340 and alleviating or controlling rapid movement of the connecting member 340 through the second protruding part 335′ because an area of the second protruding part 335′, which supports the connecting member 340, is relatively large.

FIG. 12 is a view illustrating driving of an elastic structure and movement of a connecting member of an electronic device according to an embodiment.

Referring to FIG. 12, an electronic device 300 according to an embodiment may include a side member 310 (e.g., the plate part 312), a second circuit board 322, a second rear case 332, a connecting member 340, an elastic structure 350, and a rear plate 380.

At least some of the components of the electronic device 300 illustrated in FIG. 12 may be substantially the same as or similar to the components of the electronic device 300 illustrated in FIGS. 8 to 11, and hereinafter, repeated descriptions thereof will be omitted.

1201 of FIG. 12 illustrates an operation of maintaining the elastic structure 350 in a basic state as an external force or an impact is not applied to the electronic device 300 or the applied external force or impact is removed. 1203 of FIG. 12 illustrates an operation of deforming the elastic structure 350 from the basic state as an external force or an impact that is directed in the first direction \textcircled{1} is applied to the electronic device 300. For example, when an external force is applied to the electronic device in the first direction \textcircled{1} in a state illustrated in 1201, the electronic device 300 may be deformed into a state of 1203, and when an external force in the first direction \textcircled{1} applied to the electronic device 300 is removed, or an external force is applied in the second direction \textcircled{2}, the electronic device 300 may be deformed into a state of 1201.

When an external force or an impact is applied to the electronic device 300 in the state illustrated in 1201 in the first direction \textcircled{1} in an operation of deforming the electronic device 300 from the state of 1201 to the state of 1203, at least a portion of the connecting member 340 may be moved in the first direction \textcircled{1}. As the connecting member 340 is moved in the first direction \textcircled{1}, an external force may be applied to the rod 370 of the elastic structure 350 in the first direction \textcircled{1}, and the rod 370 may be rotated within a specific range in the first rotational direction (e.g., a direction corresponding to the first direction \textcircled{1}). The movement of the connecting member 340 may be guided or controlled by a rotation operation of the rod 370, and an impact applied to the connecting member 340 may be minimized or reduced. The rod 370 may be rotated in the first rotational direction (e.g., a direction that becomes closer to a side wall 314 of the plate part 312), and a maximum or large rotation degree thereof may be restricted by the side wall 314. For example, the rod 370 may be configured not to be rotated in the first rotational direction any more when contacting the side wall 314. When being moved in the first direction \textcircled{1}, the connecting member 340 may not contact the rear plate 380 as it contacts the inclined surface 334s of the first protruding part 334 of the second rear case 332 or is moved along the inclined surface 334s.

When the electronic device 300 is deformed from the state of 1201 to the state of 1203 by an external force that is directed in the first direction \textcircled{1}, the rod 370 of the elastic structure 350 may be rotated in the second rotational direction that is opposite to the first rotational direction by a repulsive force (e.g., a repulsive force that occurs due to the twisting of the rod 370) and may return to a position of the basic state when the external force is removed or an external force that is directed in the second direction \textcircled{2} is applied. At least a portion of the connecting member 340 may be moved in the second direction \textcircled{2} as the rod 370 is rotated, and may be restored to the state of 1201. The movement of the connecting member 340 may be guided or controlled by a rotation operation of the rod 370, and an impact applied to the connecting member 340 may be minimized or reduced. When being moved in the second direction \textcircled{2}, the connecting member 340 may not contact the rear plate 380 as it contacts the inclined surface 334s of the first protruding part 334 of the second rear case 332 or is moved along the inclined surface 334s. The bent shape of the connecting member 340 may be automatically formalized into the shape illustrated in 1201 as the elastic structure 350 is restored to the basic state through the repulsive force of the rod 370.

According to various embodiments, when an excessive external force is applied to the electronic device 300 in the second direction \textcircled{2}, the rod 370 may be rotated in the second rotational direction, and the maximum or large rotation degree thereof may be restricted by the second protruding part 335. For example, the rod 370 may be configured not to be rotated in the second rotational direction any more when contacting the second protruding part 335.

FIG. 13 is a view illustrating a method for assembling an elastic structure, a second circuit board, a connecting member, and a second rear case of an electronic device according to an embodiment.

Referring to FIG. 13, the assembly method may include an operation 1301 of assembling an elastic structure 350, an operation 1303 of assembling a second circuit board 322, an operation 1305 of assembling a connecting member 340, and an operation 1307 of assembling a second rear case 332. For example, the operation 1301 of assembling the elastic structure 350, the operation 1303 of assembling the second circuit board 322, the operation 1305 of assembling the connecting member 340, and the operation 1307 of assembling the second rear case 332 may be sequentially performed.

In the operation 1301 of assembling the elastic structure 350, the elastic structure 350 may be attached to the plate part 312 of the side member 310 through an adhesive member 393. The elastic structure 350 may be coupled to a partial area of the plate part 312 that is adjacent to the battery 391. According to various embodiments, the assembly of the elastic structure 350 through the adhesive member 393 may be omitted. A through-hole 315, through which the connecting member 340 passes, may be formed in the plate part 312, and the through-hole 315 may be partially aligned with the opening 351 of the elastic structure 350.

In the operation 1303 of assembling the second circuit board 322, the second circuit board 322 may be coupled to the plate part 312 through the first fixing member 392. The second circuit board 322 may be disposed in the plate part 312 to overlap the holder 360 of the elastic structure 350, which is attached to the plate part 312, and the first fixing member 392 may pass through the second circuit board 322 and a portion of the holder 360 to be fastened to the plate part 312. For example, the elastic structure 350 may be coupled to the plate part 312 primarily through the adhesive member 393 and secondarily through the first fixing member 392. When the assembly of the second circuit board 322 is completed, the rod 370 of the elastic structure 350 may be located between the sidewall 314 of the plate part 312 and the circuit board 320.

In operation 1305 of assembling the connecting member 340, the connecting member 340 may be assembled to pass through the opening 351 of the elastic structure 350 and the through-hole 315 of the plate part 312. The connecting member 340 extends across an upper side of the battery 391, and may pass through the opening 351 and the through-hole 315.

In the operation 1307 of assembling the second rear case 332, the second rear case 332 may be coupled to the plate part 312 to cover the second circuit board 322. For example, the second rear case 332 may be coupled to the plate part 312 through the second fixing member 394, and the second fixing member 394 may pass through the second rear case 332 and the second circuit board 322 to be fastened to the plate part 312.

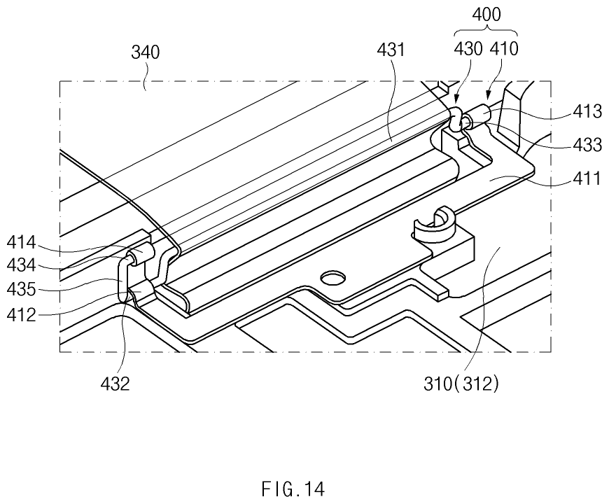

Hereinafter, a structure of the elastic structure according to various embodiments disclosed in the disclosure will be described with reference to FIGS. 14 to 19. For example, the elastic structures described with reference to FIGS. 14 to 19 may have different shapes and/or structures from those of the elastic structures according to the above-described embodiments (e.g., the elastic structure 350 of FIGS. 5 to 7), but may have substantially the same purpose and/or function and may have substantially the same overall operation. Hereinafter, in the description of the embodiments of FIGS. 14 to 19, the repeated contents of the above description will be omitted, and differences thereof will be mainly described.

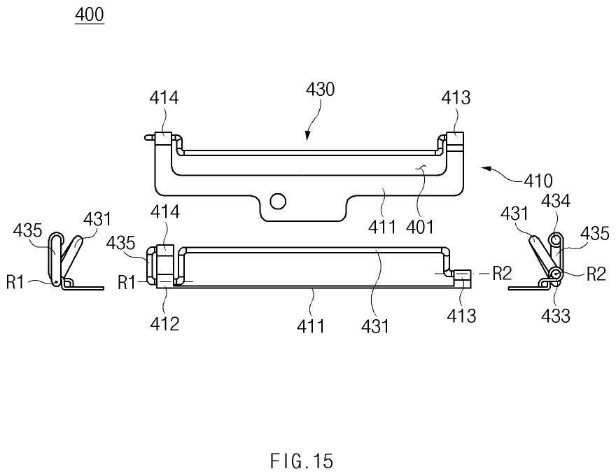

FIG. 14 is a view illustrating a connecting member and an elastic structure of an electronic device according to an embodiment. FIG. 15 is a view illustrating an elastic structure of an electronic device according to an embodiment.

Referring to FIGS. 14 and 15, an elastic structure 400 according to an embodiment may include a holder 410 (e.g., the holder 360 of FIGS. 5 to 7) and a rod 430 (e.g., the rod 370 of FIGS. 5 to 7) that is coupled to the holder 410. The elastic structure 400 may be formed in a form including a fixing shaft to further increase elasticity (or tension). For example, the elastic structure 400 according to the embodiment illustrated in FIGS. 14 and 15 may be a structure, in which a portion (e.g., a fixing part 434) that defines the fixing shaft is added to the rod and a portion (e.g., a third coupling part 414), to which the fixing part 434 is coupled, is added to the holder 360 in the elastic structure 350 of FIGS. 5 to 7. Similar to the elastic structure 350 of FIGS. 5 to 7, the elastic structure 400 of FIGS. 14 and 15 may provide elasticity by using a repulsive force that is generated while a portion and another portion of the rod 430 are rotated around the rotation axes R1 and R2 located at different heights, respectively.

The holder 410 may include a first base part 411 (e.g., the first base part 364 of FIG. 6), a first coupling part 412 (e.g., the first coupling part 365 of FIG. 6) that extends from one end of the first base part 411, a second coupling part 413 (e.g., the second coupling part 366 of FIG. 6) that extends from an opposite end of the first base part 411, and a third coupling part 414 that extends from the first coupling part 412. The third coupling part 414 may extend from the first coupling part perpendicularly thereto.

The rod 430 may include a second base part 431 (e.g., the second base part 374 of FIG. 5), a first extension part 432 (e.g., the first extension part 375 of FIG. 5) that extends from one end of the second base part 431, a second extension part 433 (e.g., the second extension part 376 of FIG. 6) that extends from an opposite end of the second base part 431, and a fixing part 434 that extends from the first extension part 432. The first extension part 432 may be coupled to the first coupling part 412 of the holder 410 to be rotatable. The second extension part 433 may be coupled to the second coupling part 413 of the holder 410 to be rotatable. The fixing part 434 may be fixedly coupled to the third coupling part 414 of the holder 410. The fixing part 434 may be parallel to the first extension part 432 and the second extension part 433. The fixing part 434 and the first extension part 432 may be connected to each other by a connecting part 435. For example, the connecting part 435 may be perpendicular to the first extension part 432 and the fixing part 434. The fixing part 434 and the first extension part 432 may overlap each other with respect to a direction, in which the connecting part 435 extends.

The first extension part 432 may form or define the first rotation axis R1. The second extension part 433 may form or define the second rotation axis R2. The first rotation axis R1 may be located closer to the plate part 312 than the second rotation axis R2. For example, the rod 430 may be formed in a shape, in which the first extension part 432 and the second extension part 433 are spaced apart from a portion of the first base part 411 that is parallel to the rotation axes R1 and R2 by different distances.

The fixing part 434 may form or define a fixing shaft. The fixing shaft indicated by the fixing part 434 may be parallel to the first rotation axis R1 and the second rotation axis R2, but may be located at a different height from the plate part 312. For example, the fixing part 434 may be located more distant from the plate part 312 than the first extension part 432 and the second extension part 433. The fixing part 434 may be a reference for a torsional displacement that occurs in the remaining portion as it is fixedly coupled to the third coupling part 414 of the holder 410. For example, the rod 430 may increase the repulsive force (e.g., an elastic force) generated by torsion as the fixing part 434 is fixed without rotating together with the remaining portions of the part.

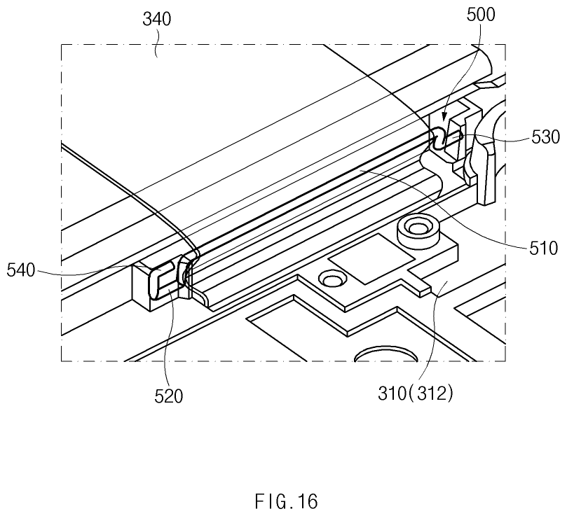

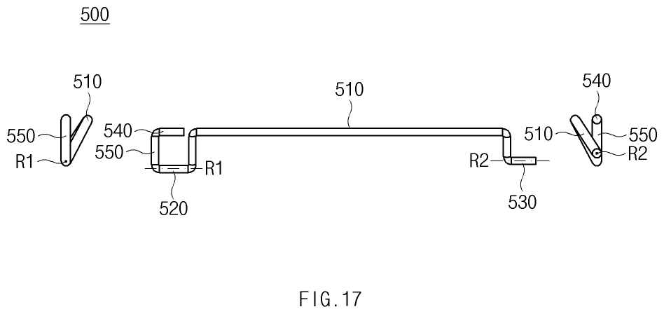

FIG. 16 is a view illustrating a connecting member and an elastic structure of an electronic device according to an embodiment. FIG. 17 is a view illustrating an elastic structure of an electronic device according to an embodiment.

Referring to FIGS. 16 and 17, an elastic structure 500 according to an embodiment may be formed in the form of a rod that is directly coupled to the side member 310 without a holder. For example, the elastic structure 500 according to an embodiment illustrated in FIGS. 16 and 17 may be a modified structure, in which the holder (e.g., the holder 410 of FIGS. 14 and 15) is omitted from the elastic structure (e.g., the elastic structure 400 of FIGS. 14 and 15) of FIGS. 14 and 15 and the rod (e.g., the rod 430 of FIGS. 14 and 15) is directly coupled to the side member 310.

The elastic structure 500 may be formed by partially bending a bar having a specific rigidity. The elastic structure 500 may include a base part 510, a first extension part 520 that extends from one end of the base part 510, a second extension part 530 that extends from an opposite end of the base part 510, and a fixing part 540 that extends from the first extension part 520. The first extension part 520, the second extension part 530, and the fixing part 540 may be parallel to each other. The fixing part 540 and the first extension part 520 may be connected to each other by a connecting part 550. For example, the connecting part 550 may be perpendicular to the first extension part 520 and the fixing part 540. The fixing part 540 and the first extension part 520 may overlap each other with respect to a direction, in which the connecting part 550 extends.

The first extension part 520 may form or define the first rotation axis R1. The second extension part 530 may be coupled to the side member 310 to be rotatable, and may form or define the second rotation axis R2. The first rotation axis R1 may be located closer to the plate part 312 than the second rotation axis R2. For example, the elastic structure 500 may be formed in a shape, in which the first extension part 520 and the second extension part 530 are spaced apart from a portion of the base part 510 that is parallel to the rotation axes R1 and R2 by different distances.

The fixing part 540 may be fixed to the side member 310. For example, the fixing part 540 may form or define a fixing shaft. The fixing shaft indicated by the fixing part 540 may be parallel to the first rotation axis R1 and the second rotation axis R2, but may be located at a different height from the plate part 312. For example, the fixing part 540 may be located more distant from the plate part 312 than the first extension part 520 and the second extension part 530. The fixing part 540 may be a reference for a torsional displacement that occurs in the remaining portion as it is fixedly coupled to the plate part 312. For example, the elastic structure 500 may increase the repulsive force (e.g., an elastic force) generated by torsion as the fixing part 540 is fixed without rotating together with the remaining portions of the part.

When an external force is applied to the elastic structure 500 in the first direction \textcircled{1}, the elastic structure 500 may be partially twisted while the first extension part 520 and the second extension part 530 of the elastic structure 500 are rotated in the first rotational direction (e.g., a direction that becomes closer to the fixing part 540) around the first rotation axis R1 and the second rotation axis R2, respectively. When the external force is removed, the first extension part 520 and the second extension part 530 may return to the state before the external force is applied while being rotated in an opposite direction (e.g., a direction that becomes more distant from the fixing part 540) to the first rotation direction around the first rotation axis R1 and the second rotation axis R2, respectively, by the restoring force of the elastic structure 500 in a twisted state.

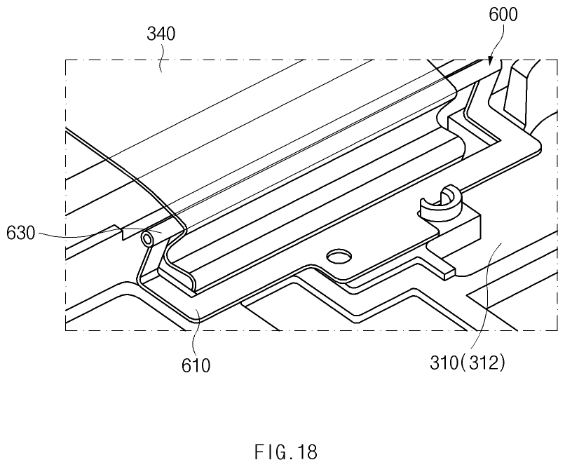

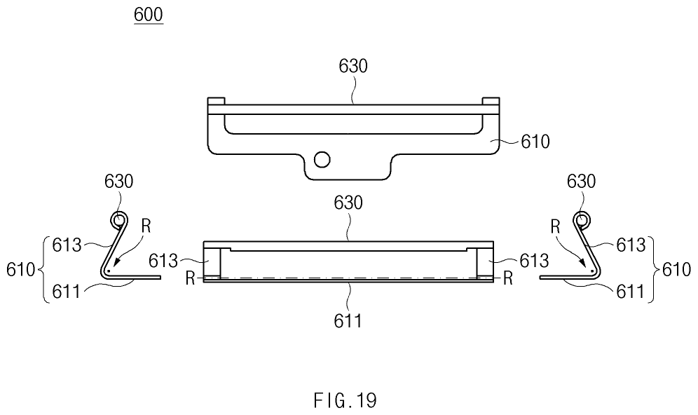

FIG. 18 is a view illustrating a connecting member and an elastic structure of an electronic device according to an embodiment. FIG. 19 is a view illustrating an elastic structure of an electronic device according to an embodiment.

Referring to FIGS. 18 and 19, in an elastic structure 600 according to an embodiment, a rod 630 that supports the connecting member 340 may be integrally formed with a holder 610. Unlike the elastic structures 350, 400, and 500 of the previous embodiments, the elastic structure 600 according to an embodiment illustrated in FIGS. 18 and 19 may provide a specific tension even when the rotation axes “R” are not located at different heights as the holder 610 itself is formed of a material having elasticity.

The holder 610 of the elastic structure 600 may be formed of a material having elasticity. The holder 610 may include a first portion 611, and second portions 613 that extend from opposite ends of the first portion 611. A rod 630 of the elastic structure 600 may be connected to the second portion 613 of the holder 610. The holder 610 may be moved in a direction, in which the second portion 613 becomes closer to or more distant from the first portion 611 by an external force, and when the external force is removed, the holder 610 may return to a state before the external force is applied by the elastic force (or a restoring force) of the holder 610. The holder 610 is a thin plate-shaped spring (e.g., a leaf spring), and may have an elastic force of a specified magnitude. For example, the holder 610 may be formed of a plate spring made of a metal material, but the disclosure is not limited thereto.

When an external force is applied to the rod 630 in the first direction \textcircled{1}, the rod 630 may be rotated around the rotation axis “R” together with the second portion 613 in the first rotational direction (e.g., a direction that becomes more distant from the first portion 611) with respect to the first portion 611, and when the external force is removed, the rod 630 may be rotated around the rotation axis “R” together with the second portion 613 in an opposite direction (e.g., a direction that becomes closer to the first portion 611) to the first rotational direction, by the elastic force of the holder 610, to return to its original position.

The electronic device may include a connecting member (e.g., an FPCB which of course include conductive material and dielectric material) for connecting an upper substrate and a lower substrate. The connecting member may extend by a sufficient length to prevent or reduce separation from the substrate. As the connecting member is formed long, it may be partially moved in an interior of the electronic device due to an impact or an external force applied to the electronic device. As the connecting member is moved, the connecting member may collide with the rear cover of the electronic device, and thus, lifting may occur in the rear cover.

Certain example embodiments provide an electronic device, in which movement of the connecting member may be guided through the elastic structure, and a bent shape of which may be formalized.

An electronic device 300 according to an example embodiment may include a housing 301 including a plate part 312, a first circuit board 321 that is disposed in the plate part to be adjacent to one side of the housing, which faces the first direction \textcircled{1}, a second circuit board 322 that is disposed in the plate part to be adjacent to an opposite side of the housing, which faces the second direction \textcircled{2} that is opposite to the first direction, a rear case 332 and 332′ that is coupled to the plate part to cover at least a portion of the second circuit board, an elastic structure 350, 400, 500, and 600 coupled to the plate part to be adjacent to the second circuit board, and configured to provide an elastic force, and a connecting member 340 connecting the first circuit board and the second circuit board, and a portion of which contacts the elastic structure. The rear case may include a first protruding part 334 and 334′ that faces a portion of the elastic structure and a portion of the connecting member, which contacts the elastic structure.

In various embodiments, the connecting member may be movable in the housing, and movement of the connecting member may be guided by the elastic structure or the first protruding part.

In various embodiments, the elastic structure may be configured such that at least a portion thereof is rotated toward the first direction or the second direction in correspondence to an external force applied to the electronic device.

The connecting member may be configured such that at least a portion thereof is moved in the first direction or the second direction based on rotation of the elastic structure.

In various embodiment, the elastic structure may include a holder 360, 410, and 610 coupled to the plate part, and a rod 370, 430, and 630 coupled to the holder. The rod may be configured such that a first end thereof is coupled to the holder to be rotatable around a first rotation axis R1, and a second end thereof being opposite to the first end is coupled to the holder to be rotatable around a second rotation axis R2. The first rotation axis and the second rotation axis may be parallel to each other, and may be spaced apart from each other by a specific distance.

In various embodiments, the elastic structure may be configured such that the first rotation axis is located at a first height H1 from the holder in a third direction \textcircled{3}, and the second rotation axis is located at a second height H2 from the holder in the third direction. The third direction may be a direction being perpendicular to the first direction and the second direction, and facing a rear surface of the electronic device.

In various embodiments, the first rotation axis and the second rotation axis may be arranged in a direction being parallel to the third direction.

In various embodiments, the elastic structure may be configured such that an opening 351 is formed between the rod and the holder. The connecting member may contact the rod and may extend to pass through the opening.

In various embodiment, a through-hole 315 aligned with the opening may be formed in the plate part. A portion of the connecting member may extend, one surface of the plate part, which faces the third direction, to an opposite surface of the plate part, which faces an opposite direction to the third direction across the rod, the opening, and the through-hole.

In various embodiments, the first protruding part may be spaced apart from the rod of the elastic structure, and a surface thereof, which faces the connecting member, may be formed to be an inclined surface 334s.

In various embodiment, the rear case further may include a body part 333 and 333′ coupled to the plate part. The first protruding part may protrude from the body part in the first direction.

In various embodiments, the rear case may further include a second protruding part 335 and 335′ protruding from the body part in the first direction such that at least a portion thereof is located in an opening of the elastic structure.

In various embodiments, at least a portion of the connecting member may be disposed in a space between a portion of the plate part and the second protruding part, and is bent in a specific shape in correspondence to a shape of the second protruding part.

In various embodiments, the rod and a partial area of the connecting member, which contacts the rod, may overlap the first protruding part and the second protruding part in the third direction.

In various embodiments, the holder may include a first base part 364 and 411 fixed to the plate part; a first coupling part 365 and 412 extending from one end of the first base part; and a second coupling part 366 and 413 extending from an opposite end of the first base part, and the first coupling part and the second coupling part may extend to be located at different heights from the first base part.

In various embodiments, the rod may include a second base part 374 and 431 which the connecting member contacts; a first extension part 375 and 432 extending from one end of the second base part and coupled to the first coupling part to be rotatable; and a second extension part 376 and 433 extending from an opposite end of the second base part and coupled to the second coupling part to be rotatable.

In various embodiments, the holder may further include a third coupling part 414 extending from the first coupling part. The rod may further include a fixing part 434 extending from the first extending part, and fixedly coupled to the third coupling part.

An electronic device 300 according to an example embodiment may include a housing 301 including a side member 310, wherein the side member may include a plate part 312 and a frame part 311 surrounding a periphery of the plate part, a first circuit board 321 disposed in the plate part adjacent to one side of the housing, which faces a first direction \textcircled{1}, a second circuit board 322 disposed in the plate part adjacent to an opposite side of the housing, which faces a second direction \textcircled{2} being opposite to the first direction, a rear case 332 and 332′ coupled to the plate part to cover at least a portion of the second circuit board, an elastic structure 350, 400, 500, and 600 coupled to the plate part adjacent to the second circuit board, and configured to provide an elastic force, and a connecting member 340 connecting the first circuit board and the second circuit board, and a portion of which contacts the elastic structure. Movement of the connecting member may be guided in an interior of the housing based on elastic deformation of the elastic structure. “Connecting” as used herein covers both direct and indirect connections.

In various embodiments, at least a portion of the elastic structure may be rotated toward the first direction or the second direction as an external force is applied to the elastic structure in a basic state, and may return to the basic state as the external force is removed.

In various embodiment, the elastic structure may include a holder 360, 410, and 610 coupled to the plate part, and a rod 370, 430, and 630 coupled to the holder. The rod may be configured such that a first end thereof is coupled to the holder to be rotatable around a first rotation axis R1, and a second end thereof being opposite to the first end is coupled to the holder to be rotatable around a second rotation axis R2. The first rotation axis and the second rotation axis may be parallel to each other, and may be spaced apart from each other by a specific distance.

In various embodiments, the elastic structure may be configured such that the first rotation axis is located at a first height H1 from the holder in a third direction \textcircled{3}, and the second rotation axis is located at a second height H2 from the holder in the third direction. The third direction may be a direction being perpendicular to the first direction and the second direction, and facing a rear surface of the electronic device.

The electronic device according to certain example embodiments may prevent or reduce chances of an impact of the connecting member by optimizing and controlling movement or deformation of the connecting member through the elastic structure.

Besides, a variety of effects directly or indirectly understood through the disclosure may be provided.

The electronic device according to certain embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that certain embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1^{st}” and “2^{nd},” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element. Thus, “coupled” and “connecting” as used herein cover both direct and indirect coupling, and direct and indirect connections.

As used in connection with various embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC). Thus, each “module” herein may comprise circuitry.

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a compiler or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to certain embodiments, each component (e.g., a module or a program) of the above-described components may include a single entity or multiple entities and some of multiple entities may be separately disposed on the other components. According to certain embodiments, one or more of the above-described components may be omitted, or one or more other components may be added. Alternatively or additionally, a plurality of components (e.g., modules or programs) may be integrated into a single component. In such a case, according to certain embodiments, the integrated component may still perform one or more functions of each of the plurality of components in the same or similar manner as they are performed by a corresponding one of the plurality of components before the integration. According to certain embodiments, operations performed by the module, the program, or another component may be carried out sequentially, in parallel, repeatedly, or heuristically, or one or more of the operations may be executed in a different order or omitted, or one or more other operations may be added.

1. An electronic device comprising:
a housing including a plate part;
a first circuit board disposed in and/or supported by the plate part adjacent to a side of the housing, which faces a first direction;
a second circuit board disposed in and/or supported by the plate part adjacent to an opposite side of the housing which faces a second direction being opposite to the first direction;
a rear case coupled to the plate part to cover at least a portion of the second circuit board;
an elastic structure, comprising elastic material, coupled to the plate part adjacent to the second circuit board, and configured to provide an elastic force; and
a connecting member, comprising conductive material, electrically connecting the first circuit board and the second circuit board, and a portion of which contacts the elastic structure,
wherein the rear case includes a first protruding part, comprising a protrusion, facing a portion of the elastic structure and a portion of the connecting member, which contacts the elastic structure.

2. The electronic device of claim 1, wherein the connecting member is configured to be movable in the housing, and
wherein the connecting member is configured so that movement of the connecting member is guided by the elastic structure and/or the first protruding part.

3. The electronic device of claim 1, wherein the elastic structure is configured such that at least a portion thereof is configured to be rotated toward the first direction or the second direction in correspondence to an external force applied to the electronic device, and
wherein the connecting member is configured such that at least a portion thereof is configured to be moved in the first direction or the second direction based on rotation of the elastic structure.

4. The electronic device of claim 1, wherein the elastic structure includes:
a holder coupled to the plate part; and a rod coupled to the holder,
wherein the rod is configured such that a first end thereof is coupled to the holder and configured to be rotatable around a first rotation axis, and a second end thereof being opposite to the first end is coupled to the holder and configured to be rotatable around a second rotation axis, and
wherein the first rotation axis and the second rotation axis are substantially parallel to each other, and are spaced apart from each other.

5. The electronic device of claim 4, wherein the elastic structure is configured such that the first rotation axis is located at a first height from the holder in a third direction, and the second rotation axis is located at a second height from the holder in the third direction, and
wherein the third direction is a direction being perpendicular to the first direction and the second direction, and facing a rear surface of the electronic device.

6. The electronic device of claim 5, wherein the first rotation axis and the second rotation axis are arranged in a direction being substantially parallel to the third direction.

7. The electronic device of claim 5, wherein the elastic structure is configured such that an opening is formed between at least the rod and the holder, and
wherein the connecting member contacts the rod and extends to pass through the opening.

8. The electronic device of claim 7, wherein a through-hole aligned with the opening is formed in the plate part, and
wherein a portion of the connecting member extends, on one surface of the plate part, which faces the third direction, to an opposite surface of the plate part, which faces an opposite direction to the third direction across the rod, the opening, and the through-hole.

9. The electronic device of claim of 8, wherein the first protruding part is spaced apart from the rod of the elastic structure, and a surface thereof, which faces the connecting member, is formed to be an inclined surface.

10. The electronic device of claim 1, wherein the rear case further includes a body part coupled to the plate part, and
wherein the first protruding part protrudes from the body part in the first direction.

11. The electronic device of claim 10, wherein the rear case further includes:
a second protruding part, comprising a protrusion, protruding from the body part in the first direction such that at least a portion thereof is located in an opening of the elastic structure.

12. The electronic device of claim 11, wherein at least a portion of the connecting member is disposed in a space between a portion of the plate part and the second protruding part, and is bent in a specific shape in correspondence to a shape of the second protruding part.

13. The electronic device of claim 11, wherein the rod and a partial area of the connecting member, which contacts the rod, overlap the first protruding part and the second protruding part in the third direction.

14. The electronic device of claim 4, wherein the holder includes:
a first base part fixed to the plate part; a first coupling part extending from one end of the first base part; and a second coupling part extending from an opposite end of the first base part, and
wherein the first coupling part and the second coupling part extend to be located at different heights from the first base part.

15. The electronic device of claim 14, wherein the rod includes:
a second base part which the connecting member contacts; a first extension part extending from one end of the second base part and coupled to the first coupling part to be rotatable; and a second extension part extending from an opposite end of the second base part and coupled to the second coupling part to be rotatable.

16. The electronic device of claim 15, wherein the holder further includes a third coupling part extending from the first coupling part, and
wherein the rod further includes a fixing part extending from the first extending part, and fixedly coupled to the third coupling part.

17. An electronic device comprising:
a housing including a side member, wherein the side member includes a plate part and a frame part surrounding a periphery of the plate part;
a first circuit board disposed in and/or supported by the plate part adjacent to a side of the housing, which faces a first direction;
a second circuit board disposed in and/or supported by the plate part adjacent to an opposite side of the housing, which faces a second direction opposite to the first direction;
a rear case coupled to the plate part to cover at least a portion of the second circuit board;
an elastic structure, comprising elastic material, coupled to the plate part adjacent to the second circuit board, and configured to provide an elastic force; and
a connecting member, comprising a dielectric material and/or a conductive material, connecting the first circuit board and the second circuit board, and a portion of which contacts the elastic structure,
wherein the connecting member and the elastic structure are configured so that movement of the connecting member is guided in an interior of the housing based on elastic deformation of the elastic structure.

18. The electronic device of claim 17, wherein at least a portion of the elastic structure is configured to be rotated toward the first direction or the second direction as an external force is applied to the elastic structure in a basic state, and returns to the basic state as the external force is removed.

19. The electronic device of claim 17, wherein the elastic structure includes:
a holder coupled to the plate part; and a rod coupled to the holder,
wherein the rod is configured such that a first end thereof is coupled to the holder to be rotatable around a first rotation axis, and a second end thereof being opposite to the first end is coupled to the holder to be rotatable around a second rotation axis, and
wherein the first rotation axis and the second rotation axis are parallel to each other, and are spaced apart from each other.

20. The electronic device of claim 19, wherein the elastic structure is configured such that the first rotation axis is located at a first height from the holder in a third direction, and the second rotation axis is located at a second height from the holder in the third direction, and
wherein the third direction is a direction being perpendicular to the first direction and the second direction, and facing a rear surface of the electronic device.
